(19) United States
(12) Patent Application Publication
(10) Pub. No.: US 2013/0115722 A1
(43) Pub. Date: May 9, 2013

(54) METHOD FOR MANUFACTURING A SEMICONDUCTOR DEVICE

(71) Applicant: Renesas Electronics Corporation, Kawasaki-shi (JP)

(72) Inventors: Hiroshi NAKAGAWA, Kanagawa (JP); Shigeru TAKADA, Kanagawa (JP); Tamotsu TANAKA, Kanagawa (JP)

(73) Assignee: RENESAS ELECTRONICS CORPORATION, Kawasaki-shi (JP)

(21) Appl. No.: 13/671,208

(22) Filed: Nov. 7, 2012

(30) Foreign Application Priority Data
Nov. 8, 2011 (JP) 2011-244733

(51) Int. Cl. H01L 21/66

(52) U.S. Cl. 438/15; 257/E21.531

(57) ABSTRACT

The manufacturing efficiency of semiconductor devices is improved. A plurality of external terminals (leads) electrically coupled with a semiconductor chip, and contact regions of a plurality of terminals (test terminals) are brought into contact with each other, respectively. This establishes an electrical coupling between the semiconductor chip and a test circuit. Thus, an electrical test is performed. Herein, the terminals are to be repeatedly used in the electrical test of a plurality of semiconductor devices. Whereas, the contact region of the terminal includes a core material formed of a first alloy, and a metal film covering the core material. Further, the metal film is formed of a second alloy higher in hardness than the first alloy.

### CROSS-REFERENCE TO RELATED APPLICATIONS

The disclosure of Japanese Patent Application No. 2011-244733 filed on Nov. 8, 2011 including the specification, drawings and abstract is incorporated herein by reference in its entirety.

### BACKGROUND

The present invention relates to a manufacturing technology of a semiconductor device. More particularly, it relates to a technology effectively applicable to a step of pressing a test terminal against an external terminal of a semiconductor device, and performing an electrical test.

In Japanese Unexamined Patent Publication No. 2002-250744 (Patent Document 1), there is described a probe needle for a semiconductor device test in which the tip end thereof is brought into contact with the electrode pad of a semiconductor device, and thus, the operation of the semiconductor device is tested.

Whereas, in Japanese Unexamined Patent Publication No. 2010-181340 (Patent Document 2), there is described an electrical test method in which a high resistance layer on the pad surface is scraped off at the time of contact with an electrode pad to perform a measurement.

Further, in Japanese Unexamined Patent Publication No. 2008-249449 (Patent Document 3), there is described a probe needle in which hard particles of diamond or the like are deposited on the tip of the base metal made of tungsten by metal plating.

Still further, Japanese Unexamined Patent Publication No. Hei 11 (1999)-111788 (Patent Document 4) describes a wafer testing probe needle formed in a long and narrow pin shape, and removal of foreign matters deposited on the probe needle tip by polishing the probe needle with a polishing wafer.

### PATENT DOCUMENTS

[Patent Document 1]
Japanese Unexamined Patent Publication No. 2002-250744
[Patent Document 2]
Japanese Unexamined Patent Publication No. 2010-181340
[Patent Document 3]
Japanese Unexamined Patent Publication No. 2008-249449
[Patent Document 4]
Japanese Unexamined Patent Publication No. Hei 11 (1999)-111788

### SUMMARY

The manufacturing steps of a semiconductor device include an electrical test step of testing whether an assembled semiconductor device (semiconductor package) has preset electrical characteristics, or operates properly. In the electrical test step, the semiconductor device is fixed to a test device, and the external terminals of the semiconductor device are brought into contact with test terminals, respectively. As a result, the testing circuit included in the test device and the semiconductor device are electrically coupled. Thus, the electrical test is performed. Further, when the test terminals are brought into contact with the external terminals of the semiconductor device to perform an electrical test, the method using long and narrow pin-shaped (needle-shaped) terminals each with the end sharpened as the test terminals is effective from the viewpoint of reducing the resistance component at the contact interface between the test terminals and the external terminals of the semiconductor device. The cusp portions of the tip of the long and narrow pin-shaped terminal are pressed against and caused to bite into the external terminal of the semiconductor device. As a result, it is possible to enlarge the contact area between the test terminal and the external terminal of the semiconductor device. Accordingly, it is possible to reduce the resistance component at the contact interface. The present inventors conducted a study on a test technology in which a test terminal is pressed against the external terminal of a semiconductor device to perform an electrical test, and a manufacturing technology of a semiconductor device, and found out the following problems.

In recent years, a study has been pursued on the reduction of the voltage of a semiconductor device, and miniaturization of external terminals. In order to perform an electrical test with stability under the influences thereof, it is important to reduce the resistance component, and to suppress the variations in resistance component when the test terminal is brought into contact with the external terminal of the semiconductor device. Under such circumstances, the present inventors conducted a study on a technology in which a metal film formed of a material higher in conductivity than the base material, such as gold (Au) is formed over the surface of a long and narrow pin-shaped (needle-shaped) base material with the end sharpened. For example, when a base material made of a carbon steel referred to as a so-called SK material is formed in a needle shape, and the surface of the base material is covered with a plating film of gold (Au), the contact resistance with the external terminal can be largely reduced.

However, in the case of the foregoing configuration, upon repeated uses for the electrical test of a plurality of semiconductor devices, the metal film covering the surface of the base material is worn or peeled, thereby to expose the internal base material. This causes an increase in contact resistance, or an increase in variations in contact resistance because the base material and the metal film are largely different in conductivity from each other. Whereas, the surface of the external terminal of the semiconductor device may be covered with a solder material from the viewpoint of improving the mounting reliability. However, in this case, the solder material is deposited on the test terminal, and tends to be oxidized. When the solder material is deposited on the test terminal, and is oxidized, the resistance component of the test terminal surface increases. This causes an increase in contact resistance, or an increase in variations in contact resistance. Particularly, when the surface of the test terminal is a gold (Au) film, the affinity between gold (Au) and a solder is high, and hence the gold film tends to be peeled from the surface of the base material. In other words, the electrical characteristics of the test terminal tend to be deteriorated by repeated uses. According to the study by the present inventors, when the test terminal is brought into contact with the external terminal of the semiconductor device about 70,000 times to 80,000 times, the results of the electrical test become unstable, resulting in the reduction of the reliability. Then, with the reduction of the reliability of the electrical test, an increase in number of retests, and an increase in number of products determined to be defective are caused, resulting in the reduction of the manufacturing efficiency of the semiconductor devices. Further, there can be considered a method in which the test terminal is replaced with another new test terminal before the reliability of the electrical test is reduced. However, an increase in replacement frequency results in an increase in maintenance load for replacement.

The present invention was completed in view of the foregoing problems. It is an object of the present invention to provide a technology of improving the manufacturing efficiency of semiconductor devices.

Further, it is another object of the present invention to provide a technology of stably reducing the resistance component when a test terminal is brought into contact with the external terminal of a semiconductor device.

Still further, it is a still other object of the present invention to provide a technology of reducing the replacement frequency of the test terminal for use in the electrical test of the semiconductor device.

The above and other objects and novel features of the present invention will become apparent from the following description of the present specification and the accompanying drawings.

Summaries of the representative ones of the inventions disclosed in the present application will be described in brief as follows.

Namely, a method for manufacturing a semiconductor device which is one embodiment of the present invention includes a step of bringing a plurality of external terminals electrically coupled with a semiconductor chip into contact with contact regions of a plurality of test terminals, respectively, thereby electrically coupling the semiconductor chip and a test circuit, and performing an electrical test. Further, the test terminals are to be repeatedly used for the electrical test of a plurality of semiconductor devices. Furthermore, the contact region of each of the test terminals includes a core material formed of a first alloy, and a metal film covering the core material. Whereas, the metal film is formed of a second alloy higher in hardness than the first alloy.

The effects obtainable by representative ones of the inventions disclosed in the present application will be described in brief as follows.

Namely, in accordance with one aspect of the present invention, it is possible to improve the manufacturing efficiency of semiconductor devices.

### BRIEF DESCRIPTION OF THE DRAWINGS

FIG. 1 is a perspective plan view showing the outline of the internal structure of a semiconductor device of one embodiment of the present invention;

FIG. 2 is a cross-sectional view along line A-A of FIG. 1;

FIG. 3 is an explanatory view showing an assembly flow of the semiconductor device shown in FIGS. 1 and 2;

FIG. 4 is a plan view showing the overall structure of a lead frame prepared in a substrate preparation step shown in FIG. 3;

FIG. 5 is an enlarged plan view showing the product formation region of FIG. 4 on an enlarged scale;

FIG. 6 is an enlarged plan view showing the state in which a semiconductor chip is mounted over the chip mounting part shown in FIG. 5 via an adhesive material;

FIG. 7 is an enlarged plan view showing the state in which a plurality of pads of the semiconductor chip and a plurality of leads of the lead frame shown in FIG. 6 are electrically coupled via a plurality of wires, respectively;

FIG. 8 is an enlarged plan view showing the state in which there is formed a sealing body sealing the semiconductor chip, the plurality of wires, and portions of the plurality of leads shown in FIG. 7;

FIG. 9 is an enlarged plan view showing the state in which the plurality of leads shown in FIG. 8 have been cut and separated;

FIG. 10 is an explanatory view schematically showing the configuration of a test device for performing the electrical test step shown in FIG. 3;

FIG. 11 is an essential part enlarged cross-sectional view showing the socket periphery of the test device shown in FIG. 1 on an enlarged scale;

FIG. 12 is an enlarged cross-sectional view showing the periphery of a test terminal shown in FIG. 11 on an enlarged scale;

FIG. 13 is a perspective view showing the contact region periphery of the test terminal shown in FIG. 12 on an enlarged scale;

FIG. 14 is a perspective view showing the contact region periphery of a test terminal which is a modified example with respect to FIG. 13 on an enlarged scale;

FIG. 15 is an enlarged cross-sectional view showing the tip portion of the contact region of the test terminal shown in FIG. 13 or 14;

FIG. 16 is an enlarged cross-sectional view showing the tip portion of the contact region of a test terminal which is a modified example with respect to FIG. 15;

FIG. 17 is an enlarged plan view showing the state in which the tip portion shown in FIG. 16 has been made flat;

FIG. 18 is an explanatory view schematically showing a manufacturing step of the terminal shown in FIG. 16;

FIG. 19 is an explanatory view schematically showing a manufacturing step of the terminal shown in FIG. 15;

FIG. 20 is an enlarged cross-sectional view showing the state in which the tip portion shown in FIG. 15 has been worn and the core material is exposed;

FIG. 21 is an enlarged plan view showing the state in which the tip portion shown in FIG. 20 has been made flat;

FIG. 22 is an enlarged cross-sectional view showing a step of polishing and regenerating the terminal with the tip end made flat.

FIG. 23 is an enlarged cross-sectional view showing a configuration of the polishing sheet shown in FIG. 22;

FIG. 24 is an enlarged cross-sectional view showing the state in which the polishing jig shown in FIG. 23 is pressed against the flattened surface of the test terminal shown in FIG. 17;

FIG. 25 is an enlarged cross-sectional view showing the direction of vibration of the polishing jig shown in FIG. 24;

FIG. 26 is a perspective plan view showing the planar positional relationship between the flat surface and the polishing jig shown in FIG. 25;

FIG. 27 is an enlarged cross-sectional view showing the state of the terminal shown in FIG. 25 after polishing;

FIG. 28 is a perspective plan view showing the terminal shown in FIG. 26 after polishing;

FIG. 29 is a perspective plan view showing the outline of the internal structure of a semiconductor device which is a modified example with respect to FIG. 1;

FIG. 30 is a plan view showing the back surface side of the semiconductor device shown in FIG. 29;

FIG. 31 is a cross-sectional view along line A-A of FIG. 29;

FIG. 32 is an explanatory view showing the assembly flow of the semiconductor device shown in FIGS. 29 to 31;

FIG. 33 is a plan view showing the overall structure of a lead frame prepared in the substrate preparation step shown in FIG. 32;

FIG. 34 is an enlarged plan view of the product formation region of FIG. 33 on an enlarged scale;

FIG. 35 is an enlarged plan view showing the back surface side of the wiring substrate shown in FIG. 34;

FIG. 36 is an enlarged plan view showing the state in which a semiconductor chip is mounted over a chip mounting part shown in FIG. 35 via an adhesive material;

FIG. 37 is an enlarged plan view showing the state in which a plurality of pads of the semiconductor chip and a plurality of bonding leads of a wiring substrate shown in FIG. 36 are electrically coupled via a plurality of wires, respectively;

FIG. 38 is a plan view showing the state in which a sealing body sealing the semiconductor chip and the plurality of wires shown in FIG. 37 is formed;

FIG. 39 is an enlarged cross-sectional view showing one example of the case where a solder ball and a contact terminal are brought in contact with each other;

FIG. 40 is a perspective view showing the contact region periphery of a test terminal which is a modified example with respect to FIGS. 13 and 14 on an enlarged scale;

FIG. 41 is an enlarged cross-sectional view showing the tip portion of the contact region of a test terminal which is a comparative example with respect to FIGS. 15 and 16;

FIG. 42 is an enlarged cross-sectional view showing the state in which the tip portion shown in FIG. 41 has been worn, and the core material is exposed;

FIG. 43 is an enlarged cross-sectional view showing the state in which a solder material is deposited over the tip portion shown in FIG. 41; and

FIG. 44 is an enlarged cross-sectional view showing the state in which a part of the tip portion shown in FIG. 43 is peeled off.

### DETAILED DESCRIPTION

[Explanation of description form, basic terms, and methods in the present application] In the present application, in the following description of embodiments, the description may be divided into a plurality of sections, or the like for convenience, if required. However, unless otherwise specified, these are not independent of each other, but, are respective parts of a single example, in a relation such that one is a detailed explanation of a part of the other, a modification example of apart or the whole, or the like of the other, irrespective of the order of description. Further, in principle, the repetitive description of the same parts will be omitted. Whereas, respective constitutional elements in embodiments are not essential, unless otherwise specified, or except for the case where the number is theoretically limiting, and unless otherwise apparent from the context.

Similarly, in the description of embodiments, and the like, the term “X including A” or the like for the material, composition, or the like does not exclude the one including an element other than A unless otherwise specified and unless otherwise apparent from the context. For example, for the component, the term means “X including A as a main component”, and the like. For example, it is naturally understood that the term “silicon member” or the like herein used is not limited to pure silicon but also embraces a SiGe (silicon germanium) alloy, other multinary alloys containing silicon as a main component, or members including other additives and the like. Whereas, the term “gold plating, Cu layer, nickel plating, or the like” herein used embraces not only pure ones, but also members including gold, Cu, nickel, and the like, respectively, as main components unless otherwise specified.

Further, also when specific numerical values and quantities are mentioned, unless otherwise specified, except when they are theoretically limited to the numbers, and unless otherwise apparent from the context, each numerical value may be a numerical value of more than the specific numerical value, or may be a numerical value of less than the specific numerical value.

Further, in respective views of embodiments, the same or similar parts are indicated with the same or similar reference sings and numerals, and a description thereon will not be repeated in principle.

Further, in the accompanying drawings, hatching or the like may be omitted even in cross section when it rather complicates the drawing, or when it is apparently distinct from the gap. In conjunction with this, when apparent from the description or the like, even for a two-dimensionally closed hole, the background outline may be omitted. Further, even not in cross section, hatching may be added in order to clearly demonstrate that the part is not a gap.

<Semiconductor Device>

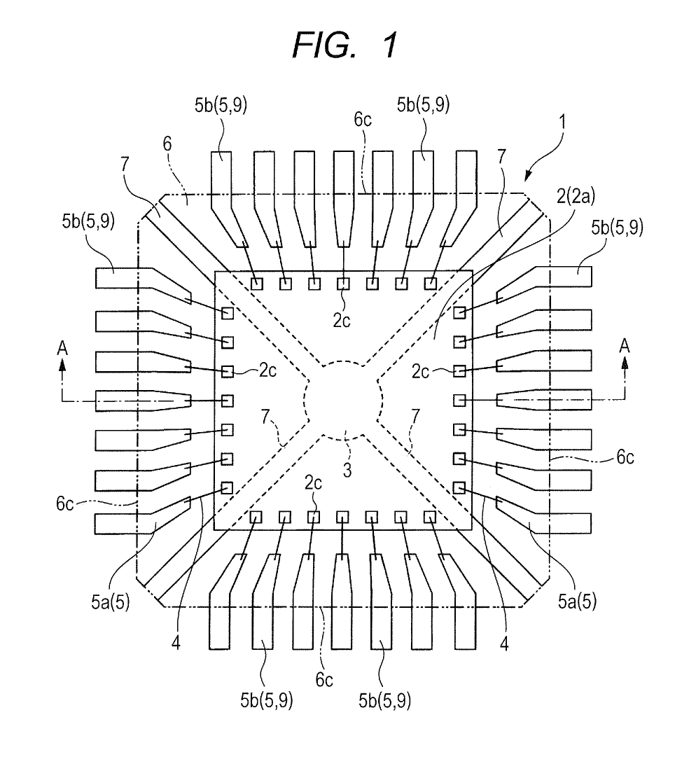

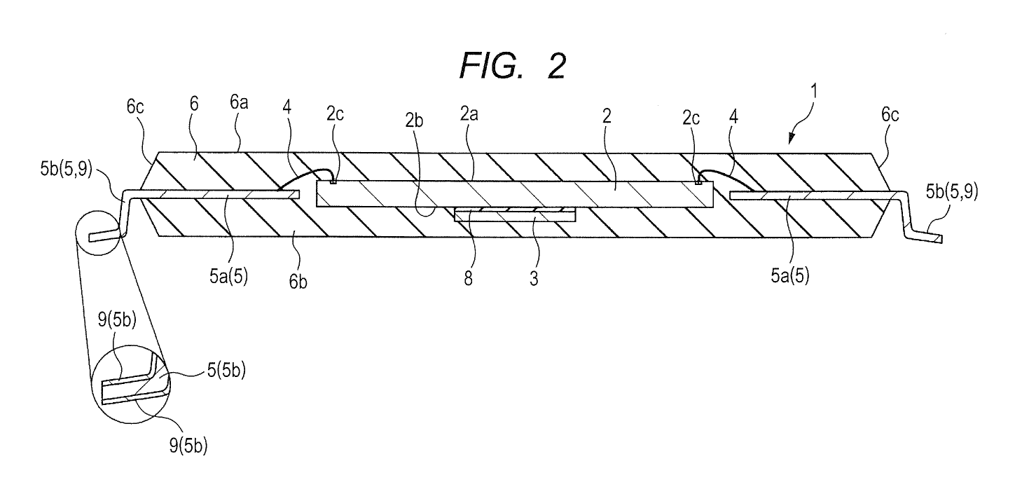

FIG. 1 is a perspective plan view showing the outline of the internal structure of a semiconductor device of the present embodiment. FIG. 2 is a cross-sectional view along line A-A of FIG. 1. Incidentally, in FIG. 1, in order to show the planar arrangement in the inside of the semiconductor device, the outline of the outer edge of the sealing body 6 is indicated with a two-dot chain line. A semiconductor device 1 which is a semiconductor device of the present embodiment shown in FIGS. 1 and 2 is a semiconductor package in which the semiconductor chip 2 is embedded in the inside of the sealing resin (sealing body) 6. Herein, a description will be given by taking, as an example, a QFP (Quad Flat Package) type semiconductor device 1 in which a plurality of outer lead parts 5b of external terminals protruding from the sealing body 6 are formed in a gull-wing shape.

The semiconductor device 1 has the semiconductor chip 2 having a front surface (main surface) 2a, a back surface (main surface) 2b situated on the opposite side of the front surface 2a, and a plurality of pads (electrode pads, chip electrodes, or terminals) 2c formed over the front surface 2a. On the front surface 2a side of the semiconductor chip 2 (specifically, the element formation surface arranged on the surface of the semiconductor substrate which is the base material of the semiconductor chip), there are formed a plurality of semiconductor elements such as transistors and diodes. The semiconductor elements are electrically coupled with the plurality of pads 2c formed over the front surface 2a. The plurality of semiconductor elements formed on the front surface 2a side of the semiconductor chip 2 are electrically coupled via wires not shown (wiring layers and chip wires) formed on the front surface 2a side (specifically, between the element formation side of the semiconductor substrate and the front surface 2a), thereby to form an electrical circuit.

Further, the semiconductor device 1 has a tab (chip mounting part or die pad) 3 for mounting the semiconductor chip 2 thereover, a plurality of leads (external terminals) 5 to be electrically coupled with the plurality of pads 2c of the semiconductor chip 2 via a plurality of wires (conductive members) 4, and a sealing body (resin or resin body) 6 sealing the semiconductor chip 2 and the plurality of wires 4. The semiconductor chip 2 is mounted (fixed) over the tab 3 supported by a plurality of suspending leads 7 (see FIG. 1) via an adhesive material 8 (see FIG. 2). The plurality of pads 2c of the semiconductor chip 2 are electrically coupled with the plurality of leads 5 which are external terminals via the wires 4, respectively. Further, the semiconductor chip 2 and the plurality of wires 4 are resin-sealed by the sealing body 6. The sealing body 6 is an insulating material obtained by adding a filler material such as silica to, for example, a thermosetting resin, and, as shown in FIG. 2, has a top surface (side) 6a, a bottom surface (side) 6b situated on the opposite side of the top surface 6a, and a side surface 6c situated between the top surface 6a and the bottom surface 6b.

Whereas, each of the plurality of leads 5 is sealed in the inside of the sealing body 6 at a part thereof (inner lead part 5a), and is exposed from the sealing body 6 at the other part (outer lead part 5b). The outer lead part 5b is the external terminal of the semiconductor device 1. Over the surface of the base material part made of, for example, copper (Cu), there is formed a metal film (solder plating film) 9 made of a solder. This metal film 9 is referred to as an exterior plating film. The metal film 9 is formed over the surface of the external terminal. As a result, when the semiconductor device 1 is mounted on a mounting substrate not shown, the wettability of the external terminal to the solder (not shown) which is a conductive bonding material can be improved. The solder forming the metal film 9 of the present embodiment is made of a so-called lead-free solder substantially not containing lead (Pb), and is, for example, only tin (Sn), tin-bismuth (Sn—Bi), tin-copper (Sn—Cu), or tin-copper-silver (Sn—Cu—Ag). Herein, the lead-free solder means the one having a content of lead (Pb) of 0.1 wt % or less. The content is determined as the standard of RoHs (Restriction of Hazardous Substances) instruction. Below, in the present embodiment, when a solder or a solder ball is described, it indicates a lead-free solder unless otherwise specified.

Incidentally, in FIGS. 1 and 2, the QFN type semiconductor device 1 is shown, wherein the plurality of leads 5 protrude from the side surface 6c of the sealing body 6. However, the structure of the semiconductor package is not limited to the example shown in FIGS. 1 and 2. For example, as a modified example, the structure of the semiconductor device is applicable to a QFN (Quad Flat Non-leaded package) type semiconductor device (not shown). In the case of the QFN type semiconductor device, a plurality of external terminals (outer lead parts) protrude from the sealing body at the bottom surface (mounting surface) of the sealing body. Even in the case of the QFN type semiconductor device, from the viewpoint of improving the wettability of the external terminals to a solder (not shown) which is a conductive bonding material at the time of mounting over a mounting substrate not shown, it is preferable to form a metal film (solder plating film) formed of a solder over the exposed surface.

<Manufacturing Method of Semiconductor Device>

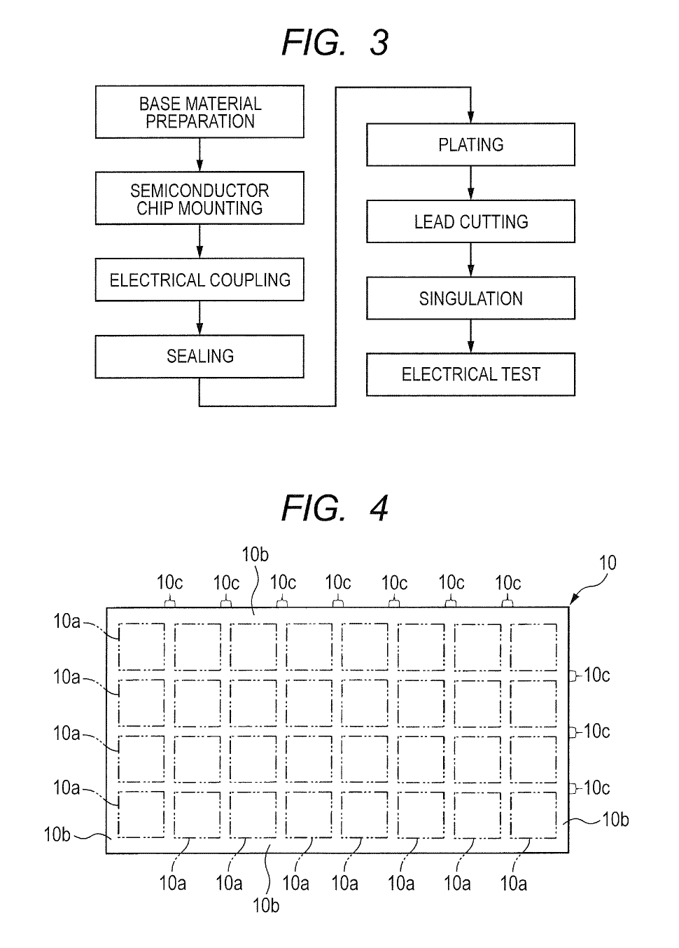

Then, a description will be given to the manufacturing steps of the semiconductor device 1 shown in FIGS. 1 and 2. FIG. 3 is an explanatory view showing an assembly flow of the semiconductor device shown in FIGS. 1 and 2. The semiconductor device 1 in the present embodiment is manufactured in accordance with the assembly flow shown in FIG. 3.

1. Base Material Preparation Step

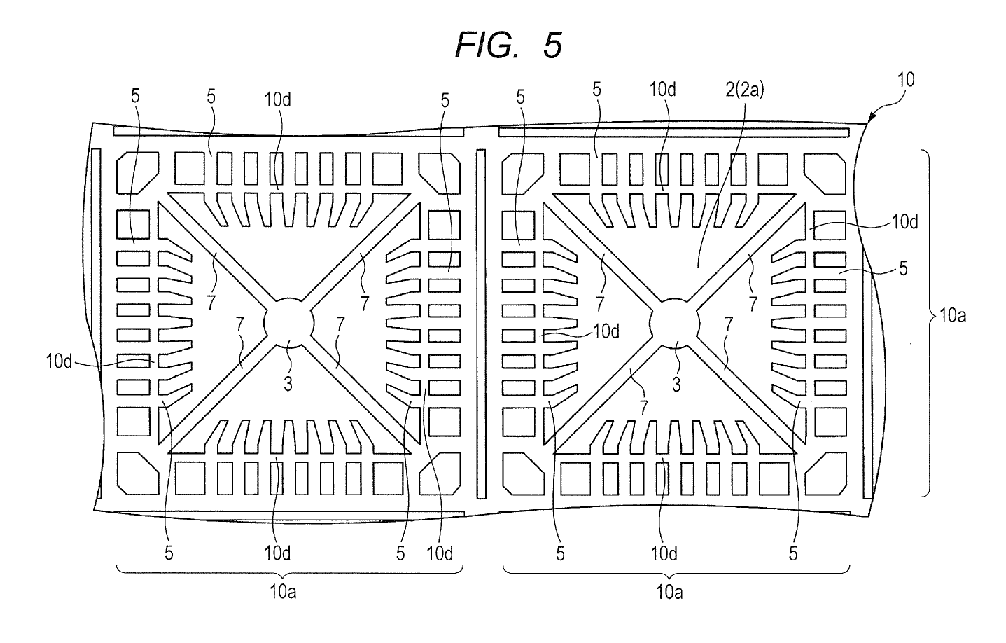

FIG. 4 is a plan view showing the overall structure of the lead frame prepared in the substrate preparation step shown in FIG. 3. FIG. 5 is an enlarged plan view showing the product formation region of FIG. 4 on an enlarged scale. First, in the base material preparation step shown in FIG. 4, the lead frame (base material) 10 shown in FIGS. 4 and 5 is prepared. Incidentally, the preparation of the lead frame (base material) 10 includes, other than the embodiment in which the lead frame 10 in the shape shown in FIGS. 4 and 5 is previously manufactured to be used, embodiments in which the lead frames 10 manufactured in other places (other offices or other entrepreneurs) are purchased to be used.

As shown in FIG. 4, the lead frame 10 prepared in the present step includes a plurality of product formation regions 10a in the inside of a frame part (frame body) 10b. Specifically, in the lead frame 10, a plurality of product formation regions 10a are arranged in a matrix. Each of the plurality of product formation regions 10a corresponds to one semiconductor device 1 shown in FIG. 1. Further, between respective product formation regions 10a, there are arranged cutting regions 10c, which are the cutting allowances, to be cut in the singulation step shown in FIG. 3. By using the lead frame 10 thus including the plurality of product formation regions 10a, it is possible to manufacture the plurality of semiconductor devices 1 (see FIG. 1) collectively. This can improve the manufacturing efficiency.

Further, as shown in FIG. 5, in each product formation region 10a of the lead frame 10 prepared in the present step, there have been already formed the tab (chip mounting part or die pad) 3, a plurality of leads (external terminals) 5 arranged around the tab 3, and the plurality of suspending leads 7 supporting the tab 3, included in the semiconductor device 1. The plurality of leads 5 are coupled with a dam part 10d, and are coupled via the dam part 10d. Whereas, the plurality of suspending leads 7 are respectively coupled with the dam part 10d, and the tab 3 is coupled with the dam part 10d via the suspending leads 7. In other words, the tab 3 and the plurality of leads 5 are supported by the lead frame 10 via the suspending leads 7 and the dam part 10d. Further, the constituent materials for the lead frame 10 are not limited to the following, but are formed by subjecting a metal plate formed of, for example, copper (Cu), a copper alloy, the one obtained by stacking a plating film of nickel (Ni) over the surface of copper, or an iron type material such as 42 alloy to a patterning treatment.

2. Semiconductor Chip Mounting Step

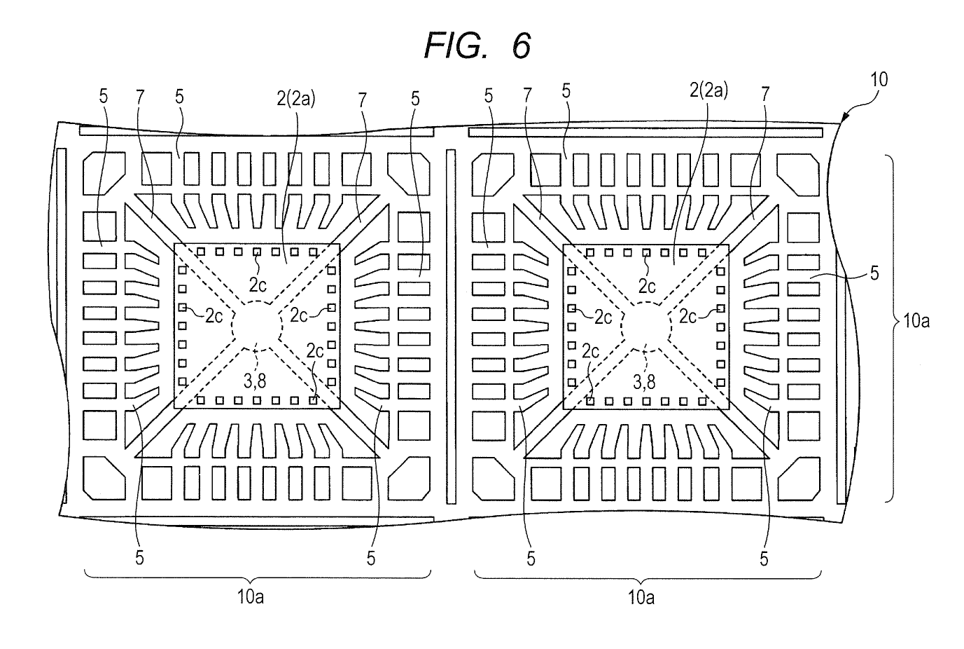

Then, in the semiconductor chip mounting step shown in FIG. 3, as shown in FIG. 6, over the tab 3 of each product formation region 10a, the semiconductor chip 2 is mounted. FIG. 6 is an enlarged plan view showing the state in which a semiconductor chip is mounted over the chip mounting part shown in FIG. 5 via an adhesive material.

In the present embodiment, the semiconductor chip 2 is mounted (bonded and fixed) via, for example, a thermosetting resin, or the adhesive material 8 obtained by mixing silver (Ag) particles in a thermosetting resin. The mounting system is, for example, a so-called face-up mounting system in which mounting is performed with the back surface 2b of the semiconductor chip 2 (see FIG. 2) opposed to the top surface of the tab 3. Incidentally, herein, a description is given by taking the structure (small tab structure) in which the size (plane area) of the tab 3 is smaller than the size (plane area) of the semiconductor chip 2 as an example. However, the size of the tab 3 is not limited thereto. The structure (large tab structure) in which the size of the tab 3 is larger than the size of the semiconductor chip 2 is also acceptable.

3. Electrical Coupling Step

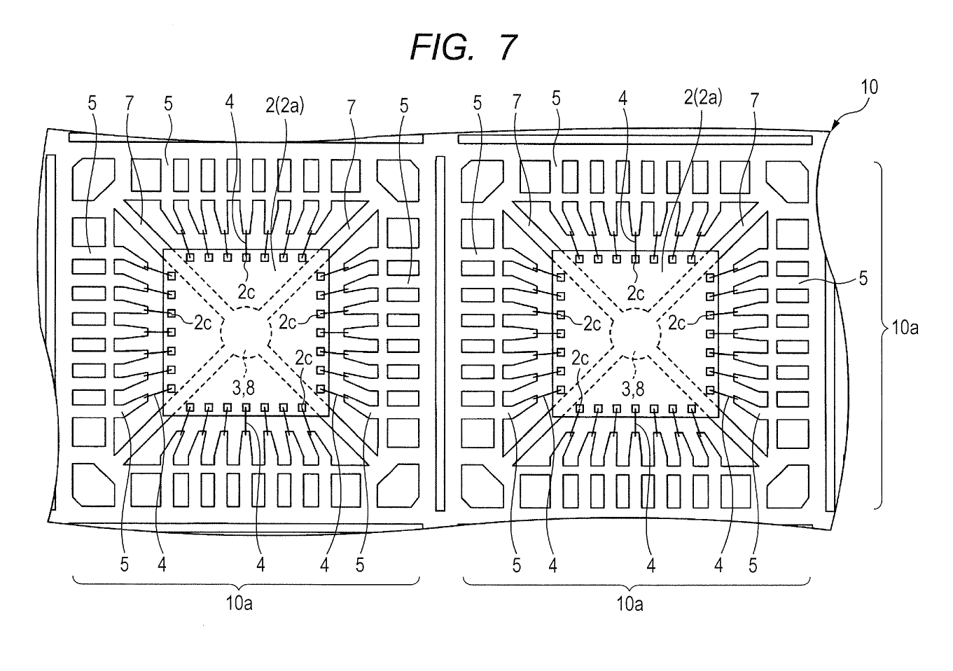

Then, in the electrical coupling step shown in FIG. 3, as shown in FIG. 7, the plurality of pads 2c of the semiconductor chip 2 and the plurality of leads 5 arranged around the semiconductor chip 2 are electrically coupled via the plurality of wires (conductive members) 4, respectively. FIG. 7 is an enlarged plan view showing the state in which a plurality of pads of the semiconductor chip and a plurality of leads of the lead frame shown in FIG. 6 are electrically coupled via a plurality of wires, respectively. In the present step, for example, a heat stage (not shown) is prepared. The lead frame 10 in which the semiconductor chip 2 is mounted over the tab 3 of each product formation region 10a is arranged over the heat stage. Then, for example, each wire 4 is supplied through a capillary (not shown). By a system of bonding the wires 4 using an ultrasonic wave and thermocompression bonding in combination, the wires 4 are coupled. Examples of the material for the wire 4 may include gold (Au), copper (Cu), and alloys thereof.

4. Sealing Step

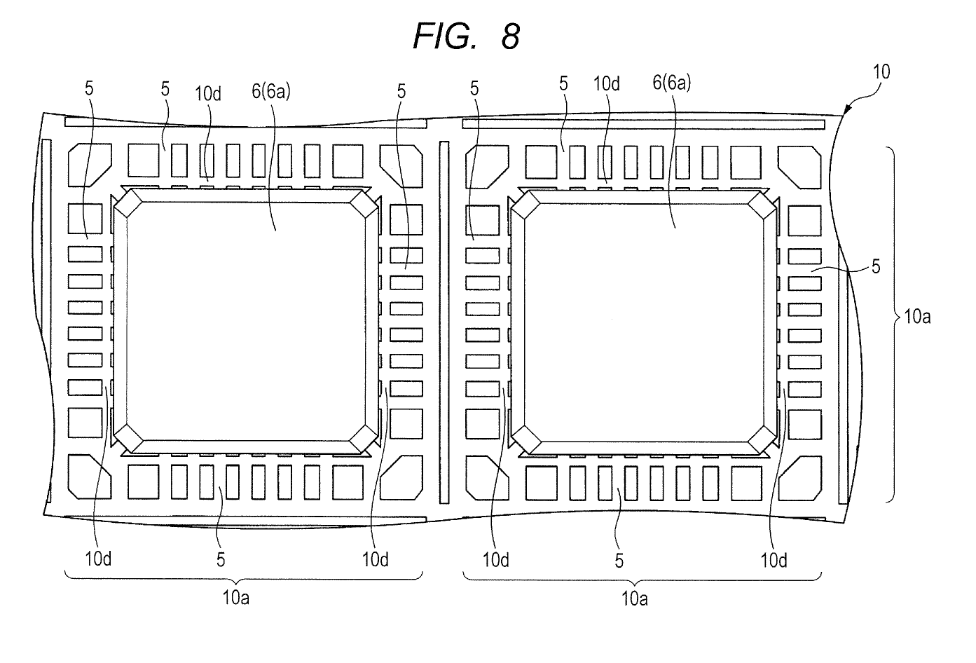

Then, in the sealing step shown in FIG. 3, as shown in FIG. 8, in each product formation region 10a, the sealing body 6 is formed. Thus, the semiconductor chip 2 (see FIG. 7), the tab 3 (see FIG. 7), the plurality of wires 4 (see FIG. 7), and a part of each of the plurality of leads 5 (inner lead parts) are sealed by the sealing body. FIG. 8 is an enlarged plan view showing the state in which there is formed a sealing body sealing the semiconductor chip, the plurality of wires, and portions of the plurality of leads shown in FIG. 7. In the present step, for example, by a so-called transfer mold system in which with the lead frame 10 shown in FIG. 7 interposed in a molding die not shown, a resin is pressed into the die, and then is cured, the sealing body 6 shown in FIG. 8 is formed. At this step, the cavity (resin pressing space) arranged in the molding die is arranged so as to be fitted in the inside of the dam part 10d shown in FIG. 8. This can inhibit the resin (sealing resin) from disorderly leaking to the outside of the dam part 10d.

5. Plating Step

Then, in the plating step shown in FIG. 3, over each surface of the plurality of leads 5 shown in FIG. 8, there is formed a metal film (plating film) formed of a solder. In the present step, for example, the lead frame 10 shown in FIG. 8 is immersed in a plating solution not shown. As a result, over the surface of the metal portion exposed from the sealing body 6, there is formed the metal film (solder plating film) 9 shown in FIG. 2. In the present embodiment, for example, the lead frame 10 is immersed in a solder solution, thereby to form the metal film which is a solder film by an electroplating system. Examples of the kind of the solder film may include tin-lead plating, pure tin plating which is Pb-free plating, and tin-bismuth plating. The metal film 9 is, as described above, formed from the viewpoint of improving the wettability of the external terminals to the solder which is a conductive bonding material at the time of mounting over the mounting substrate. However, so long as the surface of the base material part (underlayer part) formed of a metal forming the lead frame 10 is covered with the metal film 9, the thickness of the metal film 9 may be small. In the present embodiment, the thickness of the metal film 9 is smaller than that of the underlying base material part (underlayer part), and is, for example, about 10 μm to 20 μm.

6. Lead Cutting Step (Lead Forming Step)

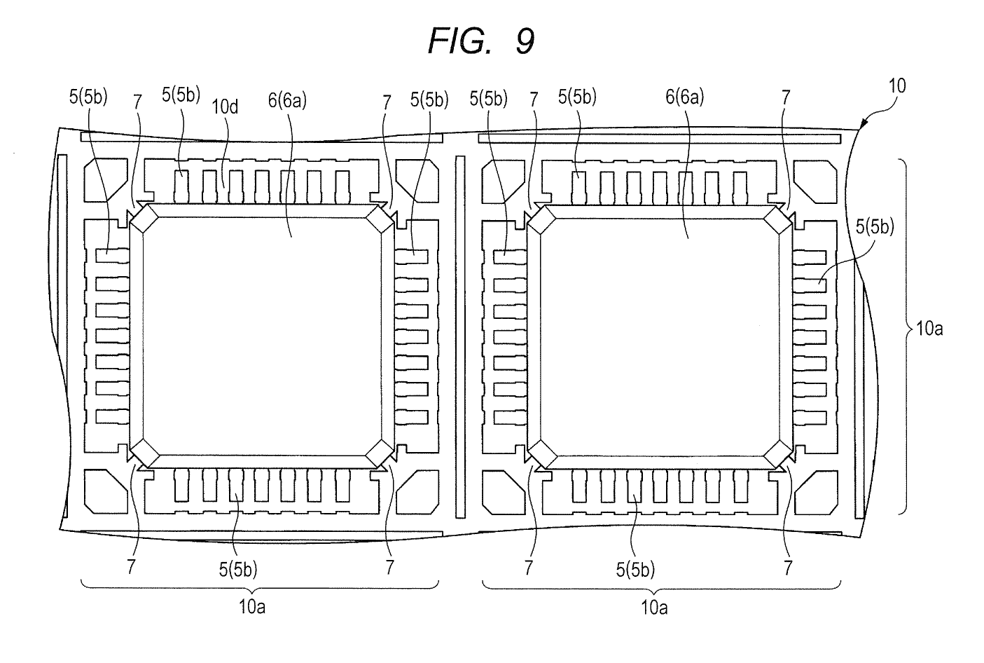

Then, in the lead cutting step shown in FIG. 3, as shown in FIG. 9, a plurality of leads 5 are cut, and separated respectively. FIG. 9 is an enlarged plan view showing the state in which the plurality of leads shown in FIG. 8 have been cut and separated. In the present step, the outer lead parts 5b of the leads 5 are cut, and cut off from the frame part 10b (see FIG. 4). Further, the dam part 10d coupling the plurality of leads 5 (see FIG. 7) are cut at between the adjacent leads 5, thereby to separate respective leads 5. The cutting method of the outer lead parts 5b of the plurality of leads 5 has no particular restriction. For example, on the bottom surface side of the lead frame 10, a punch (cutting blade) not shown is arranged, and on the top surface side, a die (supporting jig) is arranged. Thus, cutting is achieved by performing press working.

Further, the plurality of leads 5 are separated. Then, the plurality of leads 5 are formed. In the present embodiment, as shown in FIG. 2, each outer lead part 5b of the plurality of leads 5 is formed in a gull-wing shape. The method for forming each outer lead part 5b of the leads 5 has no particular restriction. For example, using forming punch and die, press working is performed. Thus, formation can be done. By the present step, the plurality of leads 5 are respectively separated, resulting in separate bodies. Further, by the present step, the plurality of leads 5 are cut off from the lead frame 10.

7. Singulation Step

Then, in the singulation step shown in FIG. 3, the suspending leads 7 shown in FIG. 9 are cut, thereby to cut off (separate) each product formation region 10a from the lead frame 10. As a result, it is possible to obtain the singulated semiconductor device 1 (see FIG. 1). The singulation method has no particular restriction. A method of cutting by press working using a cutting die is applicable. Incidentally, the plurality of semiconductor devices 1 obtained in the present step are in the form of pre-test semifinished product (assembly). Therefore, after the present step, a visual inspection step and the electrical test step shown in FIG. 3 are performed. As a result, successful devices become the semiconductor devices 1 shown in FIGS. 1 and 2.

8. Electrical Test Step

Then, in the electrical test step shown in FIG. 3, a current is passed through the semiconductor device, thereby to conduct a test for checking that there is no disconnection in the circuit, and that the device has prescribed (allowable or higher) electrical characteristics. Further, in the present step, based on the results of the electrical test, whether the device is a good product or a defective product is determined. Then, the defective products are removed. Below, the electrical test step will be described in details.

<Electrical Test Device (Inspection Device)>

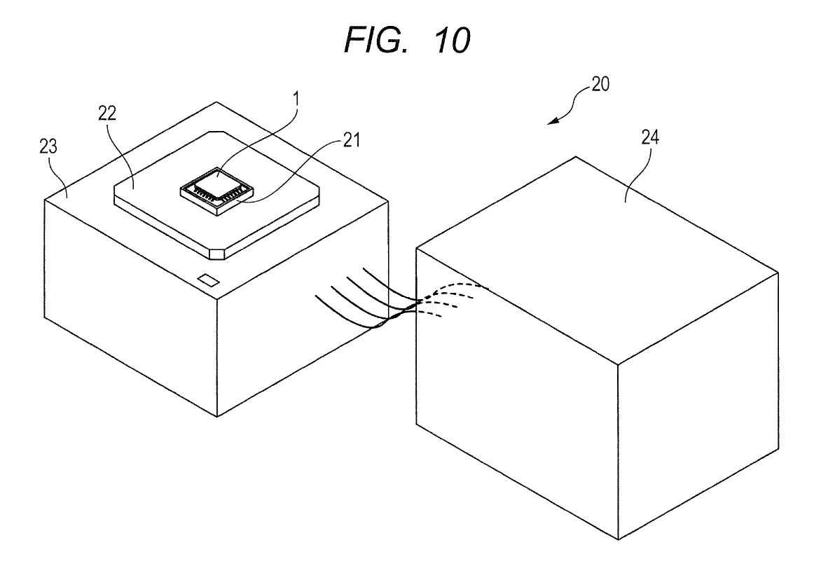

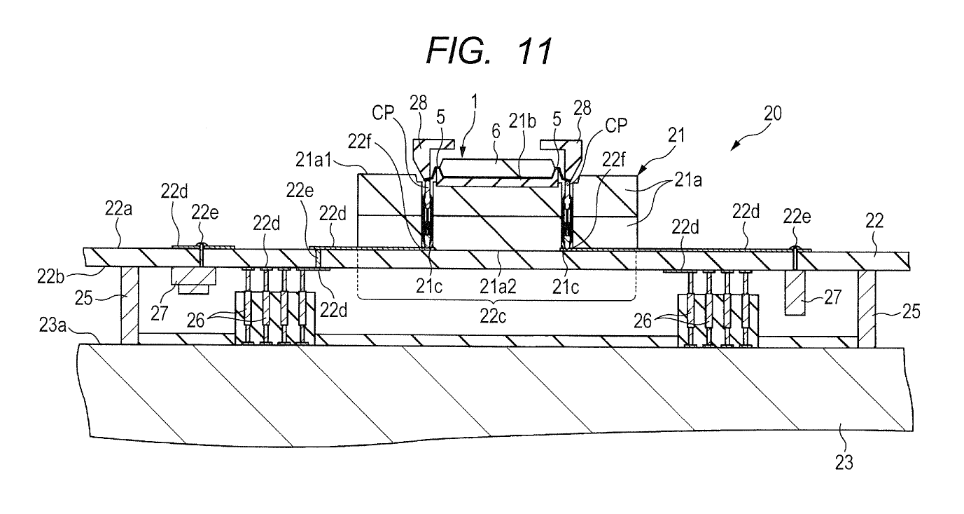

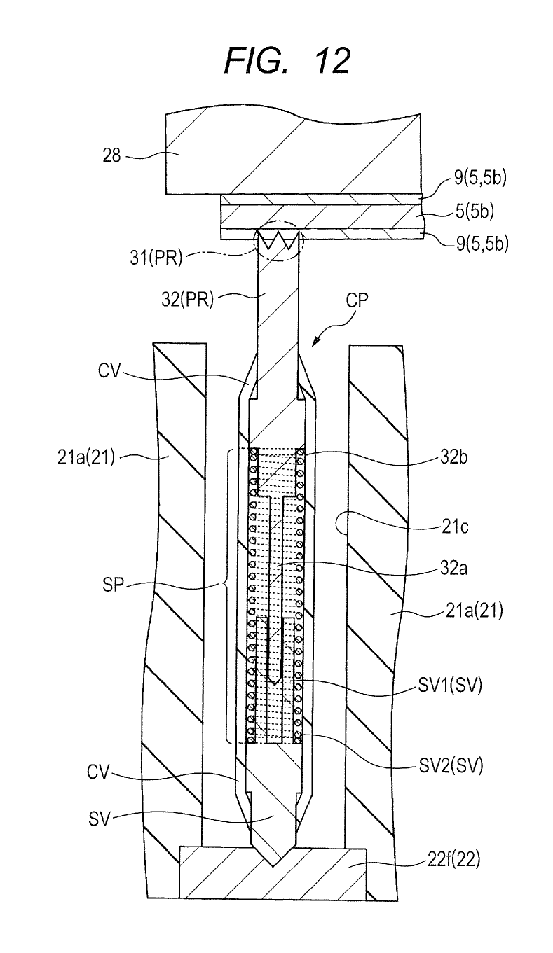

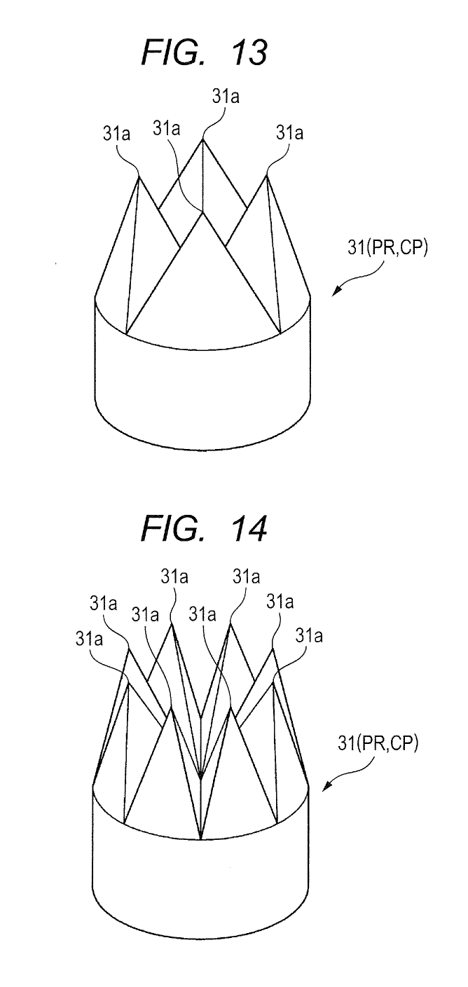

First, a description will be given to the configuration of the electrical test device (inspection device) for performing the electrical test of the semiconductor device in the electrical test step shown in FIG. 3. FIG. 10 is an explanatory view schematically showing the configuration of the test device for performing the electrical test step shown in FIG. 3. FIG. 11 is an essential part enlarged cross-sectional view showing the socket periphery of the test device shown in FIG. 10 on an enlarged scale. Whereas, FIG. 12 is an enlarged cross-sectional view showing the periphery of a test terminal shown in FIG. 11 on an enlarged scale. FIGS. 13 and 14 are each a perspective view showing the contact region periphery of the test terminal shown in FIG. 12.

A test device (an electrical test device or an inspection device) 20 for performing an electrical test on the semiconductor device 1 in the electrical test step of the present embodiment includes a socket 21 for accommodating the semiconductor device 1, a test substrate (a wiring substrate or a performance board) 22 to be electrically coupled with the semiconductor device 1 via the socket 21, and a test head 23 to be electrically coupled with the test substrate 22. In the test head 23, there is formed a test circuit for performing input/output of a signal current between it and the semiconductor device 1, which is electrically coupled with the semiconductor device 1 via the test substrate 22 and the socket 21. Further, in the present embodiment, adjacent to the test head 23, there is arranged a control part (tester main body) 24. The control part 24 is electrically coupled with the test head 23. In the control part 24, there is formed a control circuit for controlling the electrical test step (e.g., relative positional control of the test head 23 and the semiconductor device 1, or control for continuously testing the plurality of semiconductor devices 1). However, the formation site of the control circuit is not limited to the mode shown in FIG. 10. For example, as a modified example, a control circuit can be formed in the inside of the test head 23.

As shown in FIG. 11, the test head 23 has a top surface 23a which is the substrate mounting surface for mounting the test substrate 22 thereover. The test substrate 22 is fixed over the top surface 23a of the test head 23. The fixing means for fixing the test substrate 22 has no particular restriction. In the example shown in FIG. 11, over the top surface 23a of the test head 23, there is arranged a barrier plate 25. The test substrate 22 is, for example, screwed over the barrier plate 25. Further, the test substrate 22 is electrically coupled with the circuit (the test circuit) formed in the test head 23 via a plurality of connector terminals (terminals) 6 arranged over the top surface 23a of the test head 23.

Whereas, the test substrate 22 is a wiring substrate having a front surface 22a, a back surface 22b situated on the opposite side of the front surface 22a, and a socket mounting region 22c for mounting therein the socket 21 arranged over the front surface 22a. In the front surface 22a and the back surface 22b, there are formed wiring patterns including a plurality of wires 22d, respectively. The plurality of wires 22d formed on the front surface 22a side and the plurality of wires 22d formed on the back surface 22b side are electrically coupled with each other, respectively, via transmission paths (interlayer conductive paths) 22e such as through holes penetrating from the front surface 22a to the back surface 22b of the test substrate 22. Whereas, over the test substrate 22, a plurality of electronic components 27 such as capacitors and coils are mounted, and are electrically coupled with the socket 21 mounted on the front surface 22a side via the wires 22d. In the example shown in FIG. 11, the plurality of electronic components 27 are mounted over the back surface 22b. Further, the test substrate 22 is fixed over the test head 23 via a hollow space surrounded by the barrier plate 25 formed over the test head 23 so that the back surface 22b is opposed to the top surface 23a of the test head 23.

Whereas, the socket 21 for fixing the semiconductor device 1 is fixed in the socket mounting region 22c over the front surface 22a of the test substrate 22. The fixing method of the socket 21 has no particular restriction. In the present embodiment, for example, screwing is adopted. As a result, the socket 21 can be attached and removed with ease at least according to the change in type of the semiconductor device to be an object to be measured. The socket 21 includes a main body part 21a made of an insulating material such as resin. The main body part 21a includes a top surface (semiconductor device-fixing surface) 21a1 which is a surface for fixing the semiconductor device 1, and a bottom surface (test substrate-mounting surface) 21a2 situated on the opposite side of the top surface 21a1. Whereas, the socket 21 includes a fixing part (package fixing part or region) 21b arranged on the top surface 21a1 side of the main body part 21a, and for fixing and holding the semiconductor device 1. The peripheral region of the fixing part 21b protrudes from the central region of the fixing part 21b. The sealing body 6 of the semiconductor device 1 is accommodated in the inside of the protruding portion. As a result, the semiconductor device 1 can be arranged at a prescribed position. In other words, the protruding portion formed in the peripheral region of the fixing part 21b functions as a positioning guide for performing alignment of the semiconductor device 1. Further, the socket 21 includes a plurality of terminals (test terminals, contact terminals, probes, or pogo pins) CP to be electrically coupled with the plurality of leads 5 of the semiconductor device 1. The plurality of terminals CP are inserted into a plurality of through holes 21c formed in the main body part 21a of the socket 21, and are electrically coupled with a plurality of terminals (pogo seats) 22f formed over the test substrate 22, respectively. Further, over the socket 21, there is arranged a pressing jig (lead pressing member) 28 which is a lead pressing member for pressing the tip end of the lead 5 toward the terminal CP. In the electrical test step of the present embodiment, a pressing force is applied from the pressing jig 28 onto each tip end of the plurality of leads 5. Thus, each tip end of the plurality of leads 5 is pressed toward the terminal CP. As a result, the plurality of terminals CP and the plurality of leads 5 come in contact with each other, respectively, which can ensure an electrical coupling therebetween.

Further, as shown in FIG. 12, the terminal CP includes a plunger part PR having a contact region 31 to be in contact with the lead 5, a sleeve part SV arranged on the opposite side of the plunger part PR, and covering a part of the plunger part PR, and a spring part SP as an elastic body arranged between the plunger part PR and the sleeve part SV, and forms a long and narrow rod-like (needle-like) shape as a whole. In the example shown in FIG. 12, the spring part SP is a coil spring, and is configured by, for example, forming a plating film of gold (Au) (gold film) over the surface of a core material formed of spring steel. The formation of the plating film of gold over the surface of the core material can reduce the inductance component at the conductive path via the spring part SP. Whereas, the sleeve part SV is in a pointed shape (cusp shape) at one end (the lower end, or the end on the opposite side to the plunger part PR) thereof. The terminal 22f to be in contact with the sleeve part SV of the terminal CP is dented along the cusp shape of the sleeve part SV at a part of the surface thereof opposed to the sleeve part SV. Thus, by disposing the pointed portion of the sleeve part SV in the dent region, it is possible to align the terminal CP. The sleeve part SV is configured by forming a plating film of gold (Au) (gold film) over the surface of the core material formed of carbon steel referred to as a SK material. By forming the plating film of gold over the surface of the core material, it is possible to reduce the contact resistance and the inductance component of the sleeve part SV and the terminal 22f. Whereas, the other end (the upper end, or the end on the plunger part PR side) of the sleeve part SV is in a cylindrical shape. A part (shaft part) of the plunger part PR is set insertable into the inside of the cylindrical body portion SV1. This makes variable the overall length of the terminal CP (the length from the tip of the plunger part PR to the tip of the sleeve part SV). Further, at the root portion of the cylindrical body portion SV1 of the sleeve part SV, there is arranged a spring pressing surface SV2 with which one tip of the spring part SP is brought into contact. The spring pressing surface SV2 is formed integral with the cylindrical body portion SV1.

Further, the plunger part PR includes a contact region 31 which comes in contact with the lead 5 in the electrical test step, and a shaft part (shaft region) 32 extending in a rod form from the contact region 31 toward the sleeve part SV. The shaft part 32 of the plunger part PR has a function of transferring the elastic force applied from the spring part SP to the contact region 31, and adjusting the contact load (contact pressure) of the lead 5 and the contact region 31. For this reason, the shaft part 32 includes a rod-like portion 32a for being inserted into the cylindrical body portion SV1 of the sleeve part SV, and a spring pressing surface 32b arranged at the root of the rod-like portion, and with which the other tip of the spring part SP is brought into contact. The rod-like portion 32a of the shaft part 32 is inserted into the cylindrical body portion SV1 of the sleeve part SV, and hence is in a long and narrow cylindrical shape having a smaller diameter than the opening diameter of the cylindrical body portion SV1.

Whereas, the end (top end, or the end on the opposite side of the sleeve part SV) of the contact region 31 to come in contact with the lead 5 in the electrical test step is in a pointed shape (cusp shape). In the present embodiment, as shown in FIGS. 13 and 14, the contact region 31 has a plurality of cusp parts (pointed tip ends or apex parts) 31a. The number of the cusp parts 31a has no particular restriction. FIG. 13 shows an example including four cusp parts 31a, and FIG. 14 shows an example including eight cusp parts 31a. The end of the contact region 31 is sharpened to be in a cusp shape. This enables a part of the contact region 31 to bite into the lead 5 as shown in FIG. 12 in the electrical test step. Specifically, the pointed portions (the cusp parts 31a shown in FIG. 13) of the contact region 31 of the plunger part PR of the terminal CP bite into the metal film (solder plating film) 9 formed of a solder of the outer lead part 5b of the lead 5. As a result, it is possible to enlarge the contact area between the contact region 31 and the lead 5 which is an object to be inspected. This can reduce the contact resistance in the electrical test step. In other words, it is possible to reduce the resistance component when the test terminal CP is brought into contact with the lead 5 which is the external terminal of the semiconductor device 1 (see FIG. 11). Further, as exemplarily shown in FIGS. 13 and 14, in the case using the terminal CP including the plurality of cusp parts 31a, the provision of the plurality of cusp parts 31a results in an increase in number of contacts between the lead 5 (see FIG. 12) and the terminal CP. As a result, it is possible to ensure a conduction with the lead 5 through any of the plurality of cusp parts 31a. Accordingly, the test can be performed with stability. For example, even when under influences of the alignment precision and the like, the planar positional relationship between the lead 5 and the terminal CP is slightly shifted, there is a higher possibility that any of the plurality of cusp parts 31a bites into the lead 5. Therefore, when the misalignment between the lead 5 and the test terminal CP is considered, use of the terminal including a plurality of cusp parts 31a is preferable from the viewpoint of ensuring the coupling reliability between the lead 5 and the terminal CP.

<Electrical Test Step>

Then, a description will be given to the electrical test step using the test device 20 shown in FIG. 10. Incidentally, as a high-temperature test to be performed after assembling a semiconductor device, there is an accelerated test referred to as so-called burn-in. In the burn-in, a simple electrical inspection such as a continuity test may be performed. However, the burn-in and the electrical test step of the present embodiment are distinguished from each other. Namely, the burn-in is a step of detecting and removing the initial defect of a semiconductor device by acceleration with temperature and voltage, and has an object of enhancing the detection power in the final inspection of the initial fault mode failure. For this reason, in the burn-in, generally, the inspection is performed by applying a semiconductor device with a higher voltage than the voltage to be used for several hours to about 10 hours under about 125° C. environment. On the other hand, the electrical test step described in the present embodiment tests whether the electrical characteristics specified in terms of design can be obtained or not within the range of product specification.

In the present step, as shown in FIG. 11, to the fixing part 21b of the socket 21, the semiconductor device 1 which is an object to be inspected is transferred and arranged. The method for transferring the semiconductor device 1 to the socket 21 has no particular restriction. For example, automatic transfer can be achieved using a handler (transfer device) not shown. At the stage at which the semiconductor device 1 is arranged over the fixing part 21b of the socket 21, the test terminal CP and the lead 5 come in contact with each other. In order to reduce the contact resistance between the terminal CP and the lead 5, and to perform the electrical test with stability, it is preferable that a part of the terminal CP is caused to bite into a part of the lead 5. For this reason, in the present embodiment, over the fixing part 21b of the socket 21, the semiconductor device 1 is arranged. Then, the lead 5 is pressed by the pressing jig 28 for pressing the tip end of the lead 5 toward the terminal CP. As a result, the plunger part PR of the terminal CP shown in FIG. 12 is forced downwardly (toward the test substrate 22) by the pressing force from the pressing jig 28. Further, the plunger part PR is pushed downward, resulting in an increase in elastic force of the spring part SP. As a result, in the contact region 31 of the terminal CP, a biting force into the lead 5 (specifically, the metal film 9) is caused, so that the cusp parts 31a (see FIGS. 13 and 14) bite into the metal film 9 of the lead 5. The contact load between the terminal CP and the lead 5 (the load imposed on the lead 5 from the terminal CP upon contact) has no particular restriction. For example, in the present embodiment, the elastic force of the spring part SP is adjusted so as to obtain a contact load of about 20 gf (about 0.2 N) to 50 gf (about 0.5 N). Then, with the terminal CP biting into the lead 5, a current is passed through the semiconductor device 1, thereby to perform a continuity test and a test for confirming the electrical characteristics. In other words, in the present embodiment, by bringing the plurality of leads 5 and the plurality of terminals CP into contact with each other, respectively, the semiconductor chip 2 (see FIG. 2) of the semiconductor device 1 and the test circuit for an electrical test are electrically coupled, thereby to perform the electrical test.

During the test, a current is passed through the semiconductor device 1 via the plurality of terminals CP shown in FIG. 11. In addition, the signal current flowing from the semiconductor device 1 and the like are measured. As a result, it is confirmed that there is no disconnection in the circuit, and that the device has prescribed (allowable or higher) electrical characteristics. Further, based on the results of the electrical test, whether the device is a good product or a defective product is determined. Then, the defective products are removed. The classification of good products and defective products is carried out by, for example, transferring good products and defective products to different transfer destinations upon extracting the products from the socket 21.

<Detailed Configuration of Test Terminal>

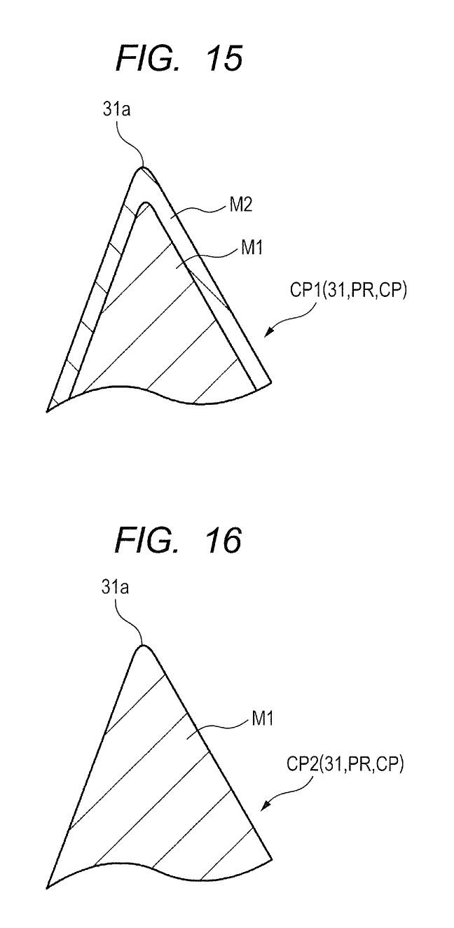

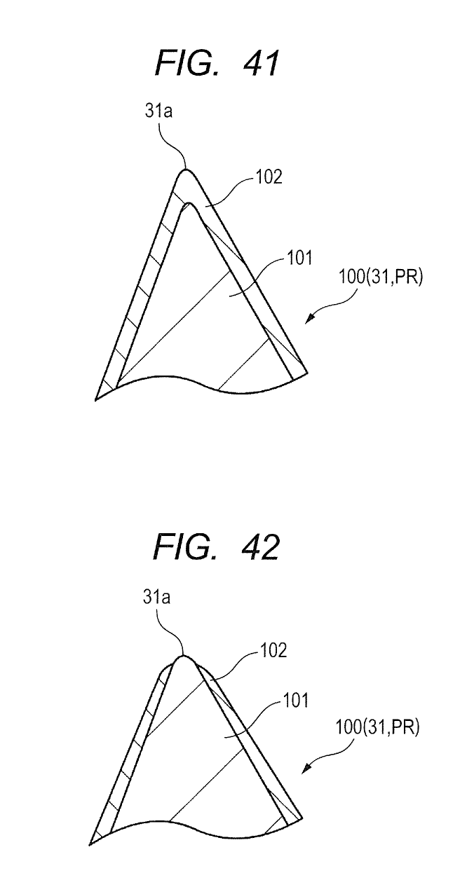

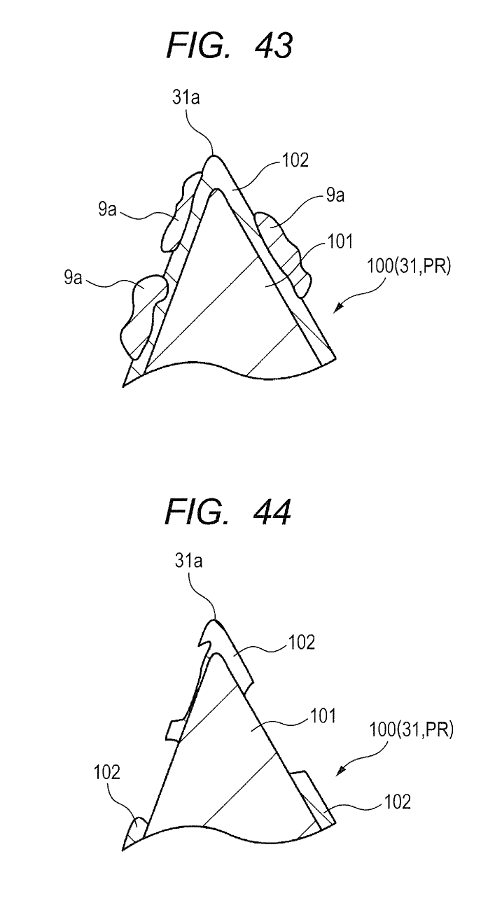

Then, a description will be given to the detailed configuration of the test terminal CP. FIG. 15 is an enlarged cross-sectional view showing the tip portion of the contact region of the test terminal shown in FIG. 13 or 14. FIG. 16 is an enlarged cross-sectional view showing the tip portion of the contact region of a test terminal which is a modified example with respect to FIG. 15. Further, FIG. 41 is an enlarged cross-sectional view showing the tip portion of the contact region of a test terminal which is a comparative example with respect to FIGS. 15 and 16. FIG. 42 is an enlarged cross-sectional view showing the state in which the tip portion shown in FIG. 41 has been worn, and the core material is exposed. FIG. 43 is an enlarged cross-sectional view showing the state in which a solder material is deposited over the tip portion shown in FIG. 41. FIG. 44 is an enlarged cross-sectional view showing the state in which a part of the tip portion shown in FIG. 43 is peeled off.

In order for the contact region 31 of the terminal CP shown in FIG. 12 to bite into the lead 5, other than sharpening of the tip end of the contact region 31, it is preferable that the metal film 9 into which the terminal CP is caused to bite is formed of a harder material than the solder material forming the metal film 9. On the other hand, from the viewpoint of reducing the contact resistance between the terminal CP and the lead 5, the outermost surface of the terminal CP is preferably covered with a metal material having a low electrical resistivity such as gold (Au). From such a viewpoint, as with the terminal 100 which is a comparative example with respect to the present embodiment shown in FIG. 41, there can be considered a test terminal 100 in which the surface of the core material 101 formed of, for example, carbon steel referred to as a so-called SK material is covered with a plating film 102 of gold (Au). Incidentally, the terminal 100 shown in FIG. 41 has the same structure as that of the terminal CP shown in FIG. 12, except for the constitutional material.

In the case where a merely only one time electrical test is considered without taking the repeating use into consideration, even when the terminal 100 shown in FIG. 41 is used, the contact resistance can be suppressed to perform the test with stability. However, in the electrical test step, from the viewpoint of manufacturing efficiency improvement, it is necessary that a plurality of (mass-produced) semiconductor devices 1 (see FIG. 11) are required to be repeatedly brought into contact with the terminal CP for performing the test. In the case of the terminal 100 shown in FIG. 41, the plating film 102 covering the surface of the core material 101 is worn or peeled, so that the core material 101 having a higher electrical resistivity than that of the plating film 102 is exposed as shown in FIG. 42 or 44. Particularly, when the surface of the core material 101 is formed of a film of gold (Au), the Au film tends to be worn. For this reason, the number of times the terminal 100 can be used until the core material 101 is exposed is small. Namely, the life is short. Further, gold (Au) has a high affinity (tends to combine) with tin (Sn) which is the main component of the solder material. For this reason, as shown in FIG. 43, a solder material 9a covering the surface of the lead 5 tends to be deposited over the surface of the plating film 102. Then, the solder material 9a deposited over the plating film 102 combines with the plating film 102, resulting in a compound. As a result, the plating film 102 becomes more likely to peel and fall off from the core material 101. Accordingly, as shown in FIG. 44, the core material 101 tends to be exposed. Whereas, even when the core material 101 is not exposed, upon oxidation of the solder material 9a (see FIG. 43) deposited over the terminal 100, the resistance component of the terminal 100 surface increases. This causes an increase in contact resistance, or an increase in variation in contact resistance. In other words, in the case of the test terminal 100, the electrical characteristics tend to be deteriorated due to repeated uses. According to the study by the present inventors, in the case of the terminal 100, when the testis performed 70,000 times to 80,000 times, the results of the electrical test become unstable, resulting in the reduction of the reliability. Then, with the reduction of the reliability of the electrical test, an increase in number of retests, and an increase in number of products determined to be defective are caused, resulting in the reduction of the manufacturing efficiency of semiconductor devices. Alternatively, there can be considered a method in which the test terminal is replaced with another new test terminal before the reliability of the electrical test is reduced. However, an increase in replacement frequency results in an increase in maintenance load for replacement.

On the other hand, in the present embodiment, as shown in FIG. 15, the contact region 31 of the terminal CP1 is formed of a core material M1 made of an alloy (first alloy), and a metal film M2 covering the core material M1. The metal film M2 is formed of an alloy (second alloy) harder (higher in hardness) than the alloy forming the core material M1. Specifically, the alloy forming the core material M1, and the alloy forming the metal film M2 are each a palladium alloy including palladium (Pd) element in the largest weight ratio among respective constituent elements. In other words, the alloy forming the core material M1 and the alloy forming the metal film M2 have the constituent element included in the largest weight ratio in common. Further specifically, the core material M1 is, for example, a palladium-silver-copper (Pd—Ag—Cu) system alloy including palladium (Pd), silver (Ag), and copper (Cu). The content ratio of respective elements is, for example, 4:3:3 by weight ratio. On the other hand, the metal film M2 is, for example, a palladium-silver (Pd—Ag) type alloy including palladium (Pd), silver (Ag), and cobalt (Co) in a weight ratio of 80:15:5, respectively. A palladium alloy mainly including a palladium element has a characteristic of being less likely to combine with tin (Sn) to be the main component of the solder material. For this reason, by covering the contact region 31 of the terminal CP1 with the metal film M2 formed of a palladium alloy, it is possible to prevent or inhibit the deposition of the solder material onto the terminal CP1. Whereas, the electrical resistivity of palladium alone is comparable to that of iron (Fe). However, addition of an accessory element thereto can make the electrical resistivity of the palladium alloy lower than the electrical resistivity of palladium alone. As such an accessory element, an element having a lower electrical resistivity than that of palladium (Pd) which is the main element, such as silver (Ag) or copper (Cu) is allowed to be included therein for alloying. As a result, it is possible to reduce the electrical resistivity to the level comparable to that of gold (Au). Incidentally, the “electrical resistivity of an element” is evaluated as the electrical resistivity in the case of a simple substance metal made of the element. For example, the element having a lower electrical resistivity than that of palladium (Pd) element refers to an element having a lower electrical resistivity than that of a simple substance metal of palladium. Silver (Ag) or copper (Cu) corresponds thereto. Whereas, the core material M1 to be covered with the metal film M2 is formed of a palladium alloy. As a result, even when the terminal CP1 is repeatedly used, thereby to expose a part of the core material M1, it is possible to prevent or inhibit the increase in contact resistance. Further, palladium (Pd) which is a main element is allowed to include cobalt (Co) as an accessory element for alloying. As a result, it is possible to improve the hardness of the alloy. Incidentally, the composition of the palladium alloy is one example specifically studied by the present inventors. Various modified examples are applicable thereto. For example, in addition to the foregoing configuration, as an accessory element, nickel (Ni) can be further allowed to be included for alloying. By allowing nickel (Ni) to be included therein, it is possible to stabilize the crystal structure of the alloy. However, nickel (Ni) element is more likely to combine with tin (Sn) than the accessory elements (silver, copper, and cobalt). For this reason, from the viewpoint of preventing the deposition of the solder material, the content ratio of nickel is preferably set equal to or lower than those of other accessory elements.

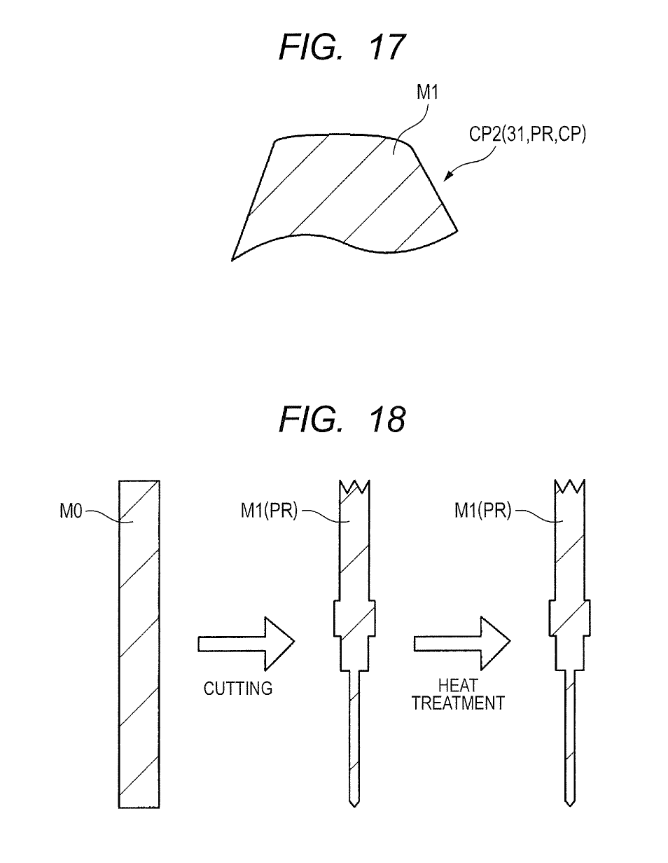

Incidentally, as with the terminal CP2 shown in FIG. 16 which is a modified example with respect to FIG. 15, it is possible to assume a structure in which the metal film M2 is not formed, and the core material M1 is exposed. In other words, one kind of solid material of a palladium alloy can form the terminal CP2. In the case of CP2 shown in FIG. 16, as compared with the terminal 100 of the comparative example shown in FIG. 41, it is possible to inhibit the reduction of the reliability of the electrical test due to repeated uses. When the contact region 31 is formed of a solid material as with the terminal CP2, even if the contact region 31 of the terminal CP2 is worn, the constituent materials of the contact region 31 do not vary. For this reason, for example, as shown in FIG. 17, the tip portion of the terminal CP2 is worn or crushed, thereby to be flattened into a flat surface 31b, and does not bite into the lead 5 (see FIG. 12) when the electrical test is performed. As a result, the contact area with the lead 5 is reduced. Thus, the electrical characteristics are stable during the period until the contact resistance increases. FIG. 17 is an enlarged plan view showing the state in which the tip portion shown in FIG. 16 has been made flat. Further, an increase in hardness of the terminal CP2 can improve the wear resistance. For this reason, it is possible to increase the number of repeated uses from the state shown in FIG. 16 until the state shown in FIG. 17. In other words, the life can be elongated.

A study by the present inventors indicates as follows: as shown in FIG. 16, the contact region 31 of the terminal CP2 is formed of only the core material M1 (only single alloy), and the hardness is set at 500 HV or more; then, the terminal CP2 can be repeatedly used about 500,000 times in the case of Vickers hardness. In other words, the life can be elongated about 7 to 8 times longer than that of the terminal 100 of the comparative example (see FIG. 41). Incidentally, as the evaluation index of the number of repeated uses, there was used the number of contacts until the contact resistance between the terminal CP and the lead 5 exceeds 1Ω. Below, except for the case where use of a different evaluation index is particularly described, the same evaluation index is used when the number of repeated uses is mentioned. Whereas, the Vickers hardness is the value obtained by dividing the test load [N] by the surface area [mm²] of the permanent indentation in the Vickers hardness test. Further, the Vickers hardness test is a hardness test in which an indenter in a pyramid shape formed of a square pyramid diamond with an angle of 136° between opposite faces is forced into the material surface, and the surface area [mm²] is calculated from the length [mm] of the diagonal line of the indentation left after removing the load. In the following description, when the hardness is described with a unit of HV, it indicates the Vickers hardness.

Further, the present inventors conducted a study on the improvement of the wear resistance of the terminal CP2 in order to further elongate the life. From the viewpoint of improving the wear resistance of the terminal CP2, it is preferable to increase the hardness of the core material M1. However, it was found as follows: when the hardness of the core material M1 is increased, the following additional problem occurs. Namely, from the viewpoint of allowing a part of the terminal CP2 to bite into the metal film 9 (see FIG. 12) of the lead 5 (see FIG. 12) in the electrical test step, the tip portion of the contact region 31 of the core material M1 is required to be in a pointed form as shown in FIG. 16. However, when the core material M1 is made hard, processing for forming the cusp shape becomes difficult. Particularly, it becomes difficult to perform processing for forming the plurality of cusp parts 31a as shown in FIGS. 13 and 14. As described above, when the core material M1 is a palladium-silver-copper (Pd—Ag—Cu) type alloy, the hardness of the core material M1 completed (after being subjected to a heat treatment as described later) is about 500 HV in terms of Vickers hardness. It is very difficult to subject a material having a hardness of about 500 HV to micromachining.

Thus, the terminal CP shown in FIG. 16 is formed, for example, in the following manner. FIG. 18 is an explanatory view schematically showing a manufacturing step of the terminal CP shown in FIG. 16. First, there is prepared a rod material (a rod-like member or a cylindrical member) M0 forming the core material M1, and made of an alloy. The hardness of the rod material M0 is, for example, about 200 HV to 300 Hv. Then, the rod material M0 is subjected to cutting (e.g., cutting using a lathe), and is formed into, for example, the shape of the plunger part PR. Then, a heat treatment is performed, thereby to harden the core material M1. As a result, the core material M1 after the heat treatment has a hardness of about 500 HV. As the heat treatment conditions, heating may be performed, for example, at around 300° C. for about 2 minutes to 3 minutes. When the hardness of the core material M1 before being subjected to a heat treatment is about 200 HV to 300 HV, even the complicated tip shape as shown in FIG. 13 or 14 can be formed relatively easily. The sleeve part SV and the spring part SP shown in FIG. 12 are separately formed, respectively. Thus, the plunger part PR, the sleeve part SV, and the spring part SP are assembled, resulting in the formation of the terminal CP. Thus, in the present embodiment, the heat treatment is performed after the formation by cutting. This results in the terminal CP2 having a hardness of about 500 HV, and having a plurality of cusp parts 31a in the contact region 31 as shown in FIG. 16. Thus, the hardness of the terminal CP2 shown in FIG. 16 can be set at about 500 HV. However, it is difficult to set the hardness of the terminal CP2 formed as a solid material still higher than 500 HV. In other words, when the terminal CP is formed of a solid material, further elongation of the life is difficult.

Thus, the present inventors further conducted a study, and found out the following: by achieving the structure of the terminal CP1 in which the surface of the core material M1 is covered with the metal film M2 harder (higher in hardness) than the core material M1 as shown in FIG. 15, it is possible to improve the wear resistance. Further, the metal film M2 which is a palladium alloy including cobalt (Co) as a constituent element can be formed by, for example, a plating method, and hence, can cover the surface of the core material M1 with ease.

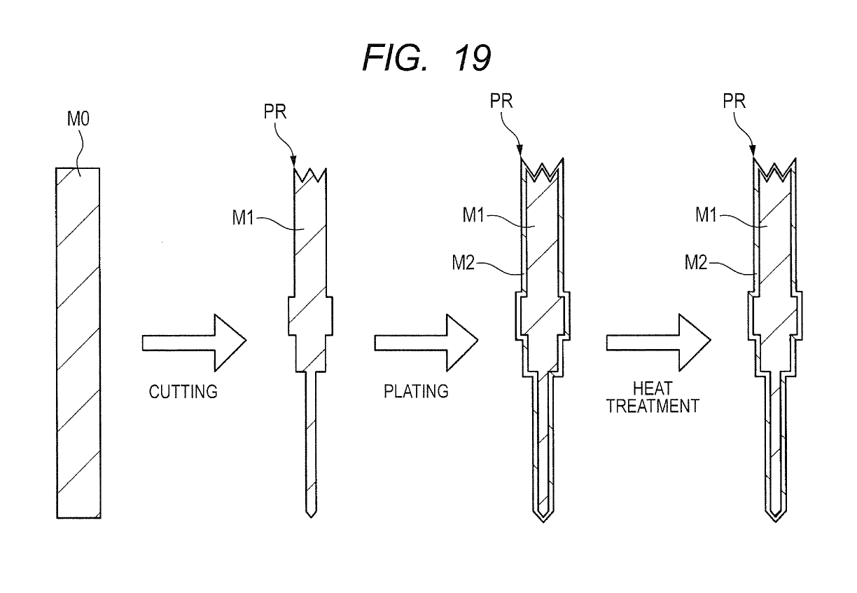

The terminal CP1 shown in FIG. 15 is formed, for example, in the following manner. FIG. 19 is an explanatory view schematically showing a manufacturing step of the terminal CP shown in FIG. 15. First, there is prepared a rod material (a rod-like member or a cylindrical member) M0 forming the core material M1, and made of an alloy. The hardness of the rod material M0 is, for example, about 200 HV to 300 Hv. Then, the rod material M0 is subjected to cutting (e.g., cutting using a lathe), and is formed into, for example, the shape of the plunger part PR. Then, the formed core material M1 is immersed in a plating solution, so that the metal film M2 is formed over the surface of the core material M1 by, for example, an electroplating method. The hardness of the metal film M2 in the state formed by the plating method is, for example, about 300 HV to 400 HV. Then, the core material M1, and the metal film M2 covering the core material M1 are subjected to a heat treatment (e.g., heated at around 300° C. for about 2 minutes to 3 minutes), thereby to harden the core material M1 and the metal film M2. The hardness of the core material M1 after the heat treatment is about 500 HV. The hardness of the metal film M2 is higher than that of the core material M1, and is, for example, about 650 HV to 700 HV. Incidentally, there can also be considered a method in which the metal film M2 is formed after subjecting the core material M1 to a heat treatment. However, in that case, the core material M1 is subjected to heat treatments plural times. For this reason, when the metal film M2 is subjected to a heat treatment, the core material M1 may be softened by annealing. Therefore, from the viewpoint of hardening the core material M1 with reliability, preferably, before subjecting the core material M1 to a heat treatment, the metal film M2 is formed, and a heat treatment is performed collectively. Further, when the core material M1 and the metal film M2 are subjected to a heat treatment collectively, the joint strength at the joint interface between the core material M1 and the metal film M2 increases. For this reason, from the viewpoint of preventing or inhibiting the metal film M2 from peeling from the core material M1, the core material M1 and the metal film M2 are preferably subjected to a heat treatment collectively.

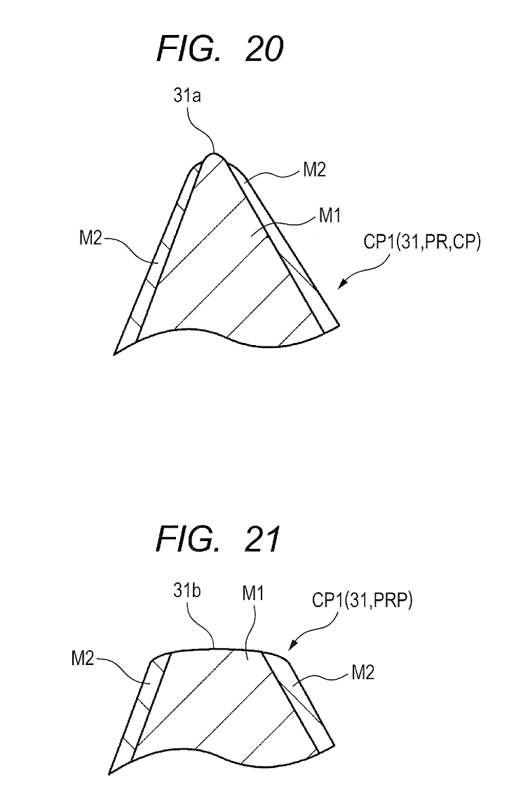

The terminal CP1 formed in the foregoing manner has a surface hardness of about 650 HV to 700 HV, and is still harder than the surface of the terminal CP2 shown in FIG. 16. For this reason, the wear resistance can be improved, and hence the life can be further elongated. FIG. 20 is an enlarged cross-sectional view showing the state in which the tip portion shown in FIG. 15 has been worn and the core material is exposed. Whereas, FIG. 21 is an enlarged plan view showing the state in which the tip portion shown in FIG. 20 has been made flat. A study by the present inventors indicates the following: when the film thickness of the metal film M2 is set at 2 μm in the terminal CP1 shown in FIG. 15, for example, as shown in FIG. 20, the terminal CP1 can be repeatedly used about 1000,000 times until the core material M1 is exposed. In other words, the life can be elongated about 14 to 16 times longer than the terminal 100 of the comparative example (see FIG. 41), and about two times longer than the terminal CP2 shown in FIG. 16.

Further, for the terminal CP1, the core material M1 and the metal film M2 are each formed of a palladium alloy. As a result, even when the core material M1 is exposed as shown in FIG. 20, it is possible to inhibit the deterioration of the electrical characteristics. In other words, the alloy forming the core material M1 and the alloy forming the metal film M2 have the element included in the largest ratio (weight ratio) in common. For this reason, even when the core material M1 is exposed, it is possible to inhibit the deterioration of the electrical characteristics. Particularly, the core material M1 and the metal film M2 each include, as an accessory element, an element having a lower electrical resistivity than that of palladium, such as silver (Ag) element. As a result, it is possible to make the electrical resitivities of the core material M1 and the metal film M2 comparable to each other. For example, as shown in FIG. 21, the tip portion of the terminal CP1 is worn or crushed, thereby to be flattened into a flat surface 31b, and does not bite into the lead 5 (see FIG. 12) when the electrical test is performed. As a result, the contact area with the lead 5 is reduced. Thus, the electrical characteristics are stable during the period until the contact resistance increases. Therefore, the present embodiment enables the following: until the metal film M2 is worn, thereby to expose the core material M1, the metal film M2 and the lead 5 (see FIG. 12) are brought into contact with each other for performing the electrical test; and after the core material M1 is exposed as shown in FIG. 20, the core material M1 and the lead 5 are brought into contact with each other for performing the electrical test. In other words, even in the case where the terminal CP1 is repeatedly used about 1000,000 times, thereby to expose the core material M1 as shown in FIG. 20, from then until the core material M1 is further worn to be flattened as shown in FIG. 21 (until the contact resistance exceeds 1Ω), it is possible to perform the electrical test with stability. In still other words, it becomes possible to use the terminal CP1 a total of about 1500,000 times of 1000,000 times until the core material M1 is exposed, and 500,000 times after the core material M1 is exposed. Further, the core material M1 and the metal film M2 are each formed of a palladium alloy. This can prevent or inhibit the following: the solder material is deposited on the terminal CP1 during about 1500,000-time repeated uses, resulting in an increase in resistance value.

Thus, in accordance with the present embodiment, it is possible to elongate the period (life) in which the resistance component when the test terminal CP1 or CP2 is brought into the lead 5 (see FIG. 11) which is the external terminal of the semiconductor device 1 (see FIG. 11). In other words, it is possible to reduce the contact resistance between the terminal CP1 or CP2 and the lead 5 with stability. For this reason, it is possible to reduce the replacement frequency of the terminal CP1 or CP2. As a result, it is possible to improve the manufacturing efficiency of the semiconductor devices 1.

Further, as compared with the plating film 102 made of gold (Au), formed over the surface of the terminal 100 shown in FIG. 41, the metal film M2 formed over the surface of the terminal CP1 shown in FIG. 15 is higher (larger) in hardness. Whereas, the core material M1 of the terminal CP1 shown in FIG. 16 is higher (larger) in hardness than the plating film 102 shown in FIG. 41. For this reason, when the terminal CP1 or CP2 is brought into contact with the lead 5 (see FIG. 12), it is possible to reduce the deformation amount of the contact region 31 of the terminal CP1 or CP2 (the amount to be cut by wear, the amount to be collapsed by a pressing force, or the amount to fall off due to the deposition of a solder). Further, when the terminal CP1 or CP2 is repeatedly used, there is produced an effect of reducing the deformation amount of the contact region 31 each time when the terminal CP1 or CP2 is brought into contact with the lead 5. As a result, the life of the terminal CP1 or CP2 is elongated, which can increase the number of contacts.

<Regeneration Treatment Method of Test Terminal>

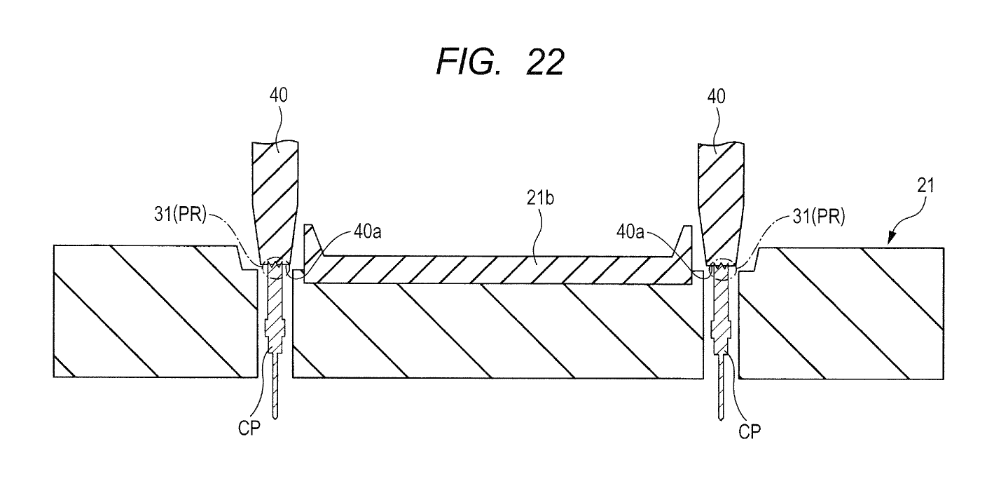

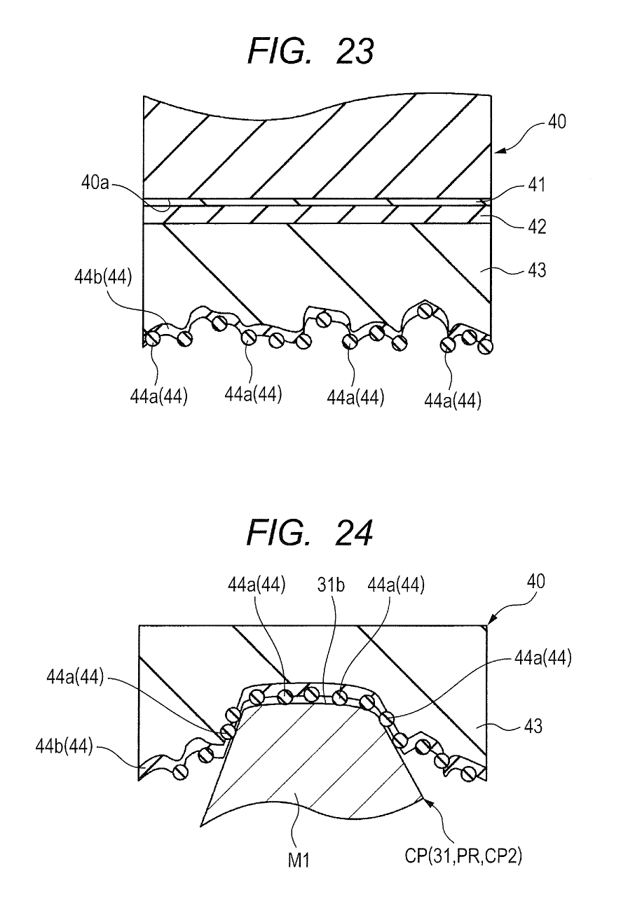

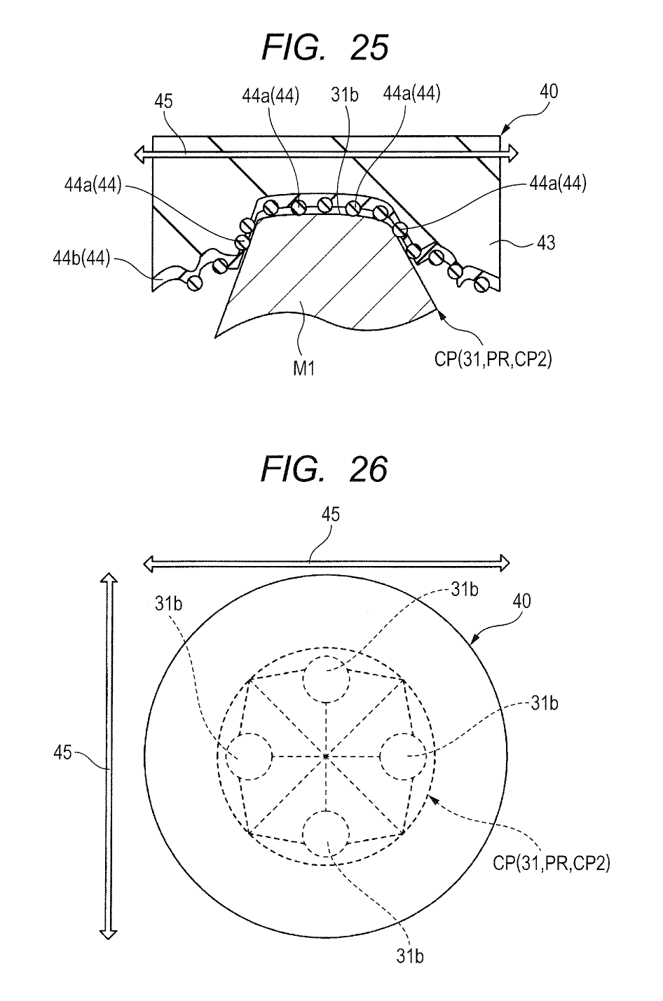

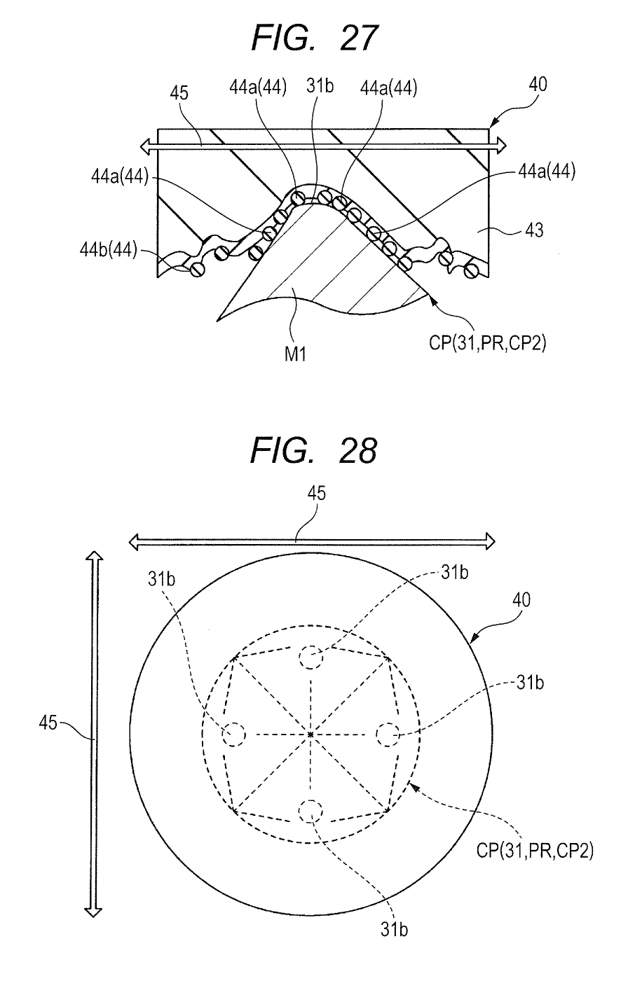

As described above, the terminal CP1 or CP2 can be largely elongated in life than the terminal 100 of the comparative example. However, as shown in FIGS. 17 and 21, the terminal CP1 or CP2 can be further elongated in life by being subjected to a regeneration treatment after being flattened. Below, a detailed description will be given to a method in which after flattening of the tip portion as shown in FIG. 17 or 21, a regeneration treatment is performed. FIG. 22 is an enlarged cross-sectional view showing a step of polishing and regenerating the terminal with the tip end made flat. Further, FIG. 23 is an enlarged cross-sectional view showing a configuration of the polishing sheet shown in FIG. 22. Whereas, FIG. 24 is an enlarged cross-sectional view showing the state in which the polishing jig shown in FIG. 23 is pressed against the flattened surface of the test terminal shown in FIG. 17. Further, FIG. 25 is an enlarged cross-sectional view showing the direction of vibration of the polishing jig shown in FIG. 24. FIG. 26 is a perspective plan view showing the planar positional relationship between the flat surface and the polishing jig shown in FIG. 25. Further, FIG. 27 is an enlarged cross-sectional view showing the state of the terminal shown in FIG. 25 after polishing. FIG. 28 is a perspective plan view showing the terminal shown in FIG. 26 after polishing. Incidentally, FIGS. 24 to 28 each exemplarily show the method for performing a polishing treatment on the terminal CP2 shown in FIG. 17 for simplification. The method is also similarly applicable to the case where a polishing treatment is performed on the terminal CP1 shown in FIG. 21.

In the present embodiment, the terminal CP with the tip end flattened as shown in, for example, FIG. 17 or 21, is subjected to a polishing treatment, thereby to sharpen again and regenerate the end thereof. As described above, in the present embodiment, the contact region of the terminal CP is made of alloy materials including the main element in common. Accordingly, even when the surface is cut off, the electrical characteristics can be prevented or inhibited from being reduced. For this reason, it is possible to polish and perform a regeneration treatment on the tip end.

Specifically, as shown in FIG. 22, with a plurality of terminals CP mounted to the socket 21, polishing jigs 40 are pressed against respective ends of the contact regions 31 of the plurality of terminals CP, respectively. Over one surface (polishing surface 40a) of the polishing jig 40, as shown in FIG. 23, an adhesive layer 41, a film layer 42, an elastic body layer 43, and a polishing abrasive grain layer 44 are successively stacked. The film layer 42 is a resin film of, for example, PET (polyethylene terephthalate). Over one surface thereof, the adhesive layer (adhesion layer) 41 is formed; and over the other surface, the elastic body layer 43 is formed. Whereas, the elastic body layer 43 formed over the bottom surface of the film layer 42 is formed of an elastic body such as foamed urethane so that when the polishing jig 40 is pressed against the terminal CP (see FIG. 22) for polishing, the polishing abrasive grain layer 44 is elastically deformed following the to-be-polished surface. Further, in the polishing abrasive grain layer 44 formed over one surface (bottom surface) of the elastic body layer 43, a plurality of abrasive grains 44a which are, for example, alumina (Al₂O₃) particles with a grain size of about 3 μm are bonded to the elastic body layer 43 via the resin adhesive material 44b.

When the polishing jig 40 is pressed against the end of the contact region 31 of the terminal CP, as shown in FIG. 24, the elastic body layer 43 is elastically deformed following the to-be-polished surface (the flat surface 31b worn and flattened by repeated uses) of the terminal CP. Accordingly, the plurality of abrasive grains 44a come in contact with the contact region 31 of the terminal CP. In other words, the to-be-polished surface (the flat surface 31b worn and flattened by repeated uses) of the terminal CP bites into the elastic body layer 43 formed over the polishing surface 40a of the polishing jig 40 (see FIG. 23). Accordingly, the plurality of abrasive grains 44a come in contact with the periphery of the to-be-polished surface. The contact load between the polishing jig 40 and the terminal CP at this step can be controlled by the pressing force for forcing the polishing jig 40 toward the terminal CP, and the spring part SP (see FIG. 12) of the terminal CP.

Then, as indicated with arrows 45 in FIGS. 25 and 26, the polishing jig 40 is vibrated while being pressed against the terminal CP (with the terminal CP biting thereinto), thereby to polish the flattened surface of the terminal CP. As a result, the peripheral part of the flat surface 31b shown in FIG. 25 is preferentially polished. Accordingly, as shown in FIG. 27, the end of the terminal CP can be sharpened again. Incidentally, the degree of sharpening the end of the terminal CP is particularly preferably the degree resulting in the same state as before the start of use (e.g., the state shown in FIG. 16). However, this polishing step is performed after hardening of the core material M1 to about 500 HV. For this reason, sharpening to the same state as before the start of use requires a longer polishing treatment time. Further, as shown in, for example, FIGS. 27 and 28, when the area of the flat surface 31b becomes smaller than before polishing, in the electrical test step, a part of the contact region 31 of the terminal CP can be caused to bite into the lead 5. Therefore, at least in the present step, by performing a polishing treatment until the area of the flat surface 31b becomes smaller than before the start of the polishing treatment, it is possible to regenerate the terminal CP. In the present step, the degree of sharpening the tip of the terminal CP also varies according to the material and shape of the terminal against which the terminal CP is pressed. However, effectively, it is particularly preferable that the polishing treatment is performed until the area of the flat surface 31b becomes half or smaller.

Further, when the polishing treatment is performed, as shown in FIG. 25, the polishing jig 40 is preferably vibrated along the flat surface 31b (in the horizontal direction). As a result, it is possible to efficiently polish the peripheral part of the flat surface 31b. Alternatively, preferably, as shown in FIG. 26, the polishing jig 40 is vibrated in a plurality of directions crossing each other (e.g., in FIG. 26, two directions orthogonal to each other) along the flat surface 31b (in the horizontal direction), or the polishing jig 40 is rotationally moved along the flat surface 31b. As a result, it is possible to prevent or inhibit the occurrence of an insufficiently polished region in the peripheral part of the flat surface 31b.

Incidentally, as the method for subjecting the terminal CP to a polishing treatment, there can be considered a method in which the terminal CP is removed from the socket 21 to be polished. However, after removing the terminal CP from the socket 21 and polishing it, reassembling thereof becomes necessary, resulting in a complicated operation. In the present embodiment, the plurality of terminals CP are regenerated while being attached on the socket 21. Accordingly, it is possible to improve the operation efficiency, in other words, the manufacturing efficiency of the semiconductor devices including the regeneration efficiency.

### Modified Example

Up to this point, the invention made by the present inventors was specifically described by way of embodiments. However, the present invention is not limited to the embodiments. It is naturally understood that various changes may be made within the scope not departing from the gist.

For example, in the foregoing embodiments, a description was given to the embodiments in which the whole plunger part PR of the terminal CP is formed of a palladium alloy. However, so long as at least the contact region 31 of the terminal CP is formed of an alloy, or an alloy satisfying the conditions described by reference to FIGS. 15 and 16, the configuration of other portions is not limited thereto. However, when the ease of formation of the plunger part PR is considered, it is preferable that the whole plunger part PR of the terminal CP is formed of a palladium alloy as described in the embodiments.

Further, for example, in the embodiments, a description was given to the embodiments in which the core material M1 is worn and flattened, and then is polished and regenerated. However, a modified example thereof may be an embodiment as follows: the polishing step is not performed; and at the state in which the core material M1 is worn and flattened (the state shown in FIG. 17 or 21), the plurality of terminals CP are replaced with new ones, or the plurality of terminals CP together with the socket 21 are replaced with new ones. From the viewpoint of elongation of the life of the terminal CP, it is preferable that a regeneration treatment is performed. However, from the viewpoint of improvement of the manufacturing efficiency, the polishing treatment may not be performed because the number of operations required for the polishing treatment increases.

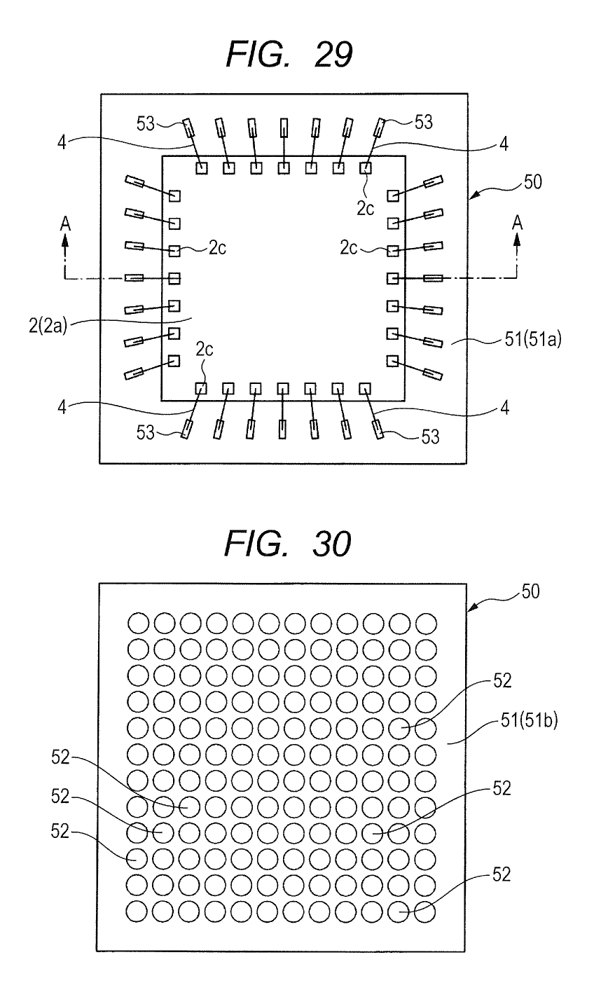

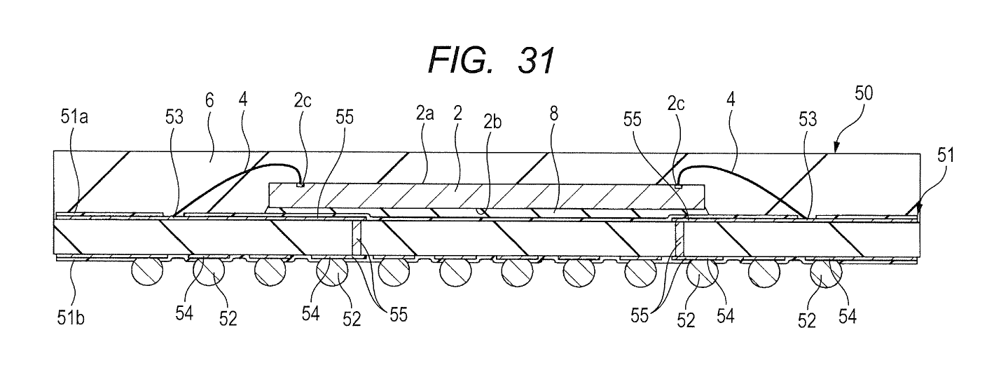

Further, in the embodiment, the structure in which the socket 21 is directly mounted on the test substrate 22 was described as one example of the inspection device. However, the mounting structure of the socket 21 is not limited thereto. For example, the socket 21 is mounted on an interface substrate not shown, so that the interface substrate can be electrically coupled with the test substrate 22. This case is advantageous in that when a change in the coupling circuit occurs due to a product change or the like, a modification of the interface substrate may be adaptable thereto. However, from the viewpoint of shortening the distance of the conductive path for electrically coupling the test circuit and the socket 21, as described in the embodiment, it is preferable that the socket 21 is directly mounted on the test substrate 22.

Whereas, in the embodiment, as the example of the semiconductor device to be an object to be inspected, the QFP type semiconductor device 1 was taken up and described. However, the package form of the semiconductor device to be an object to be inspected is not limited to the lead frame type such as the QFP type. For example, the package form is applicable to a so-called area array type semiconductor device 50 as follows: as shown in FIGS. 29 and 30, the semiconductor chip 2 is mounted over the wiring substrate 51 which is a base material; on the side (back surface 51b) of the wiring substrate opposite to the chip mounting surface, (front surface 51a) a plurality of external terminals (solder balls 52) are arranged in rows and columns (in a matrix). FIG. 29 is a perspective plan view showing the outline of the internal structure of the semiconductor device which is a modified example with respect to FIG. 1. FIG. 30 is a plan view showing the back surface side of the semiconductor device shown in FIG. 29. FIG. 31 is a cross-sectional view along line A-A of FIG. 29. Incidentally, FIG. 29 is a perspective plan view, and hence the sealing body 6 shown in FIG. 31 is not shown. Below, a description will be mainly given to the difference from the semiconductor device 1 described in the embodiment briefly.

The semiconductor device 50 has the semiconductor chip 2 mounted over the front surface 51a of the wiring substrate 51, a plurality of conductive members (wires 4 in the present embodiment) for electrically coupling the semiconductor chip 2 and the wiring substrate 51, a sealing body (resin body) 6 for sealing the semiconductor chip 2 and the plurality of wires 4, and a plurality of solder balls (external terminals or solder materials) 52 formed on the back surface 51b side of the wiring substrate 51, and electrically coupled with the semiconductor chip 2. Incidentally, the solder balls 52 are external terminals for electrically coupling the semiconductor device 1 and the mounting substrate (mother board), and are each formed of the lead-free solder.

In the example shown in FIGS. 29 to 31, by a so-called face-up mounting system in which mounting is performed with the back surface 2b of the semiconductor chip 2 opposed to the front surface 51a of the wiring substrate 51, the semiconductor chip 2 is mounted over the wiring substrate 51 with is a base material. With the face-up mounting system, the semiconductor chip 2 and the wiring substrate 51 are electrically coupled by a wire bonding system. Namely, the plurality of pads 2c formed over the front surface 2a of the semiconductor chip 2 and the plurality of bonding leads (terminals, or bonding pads) 53 arranged around the semiconductor chip 2 in plan view so as to be exposed on the front surface 51a side of the wiring substrate 51 are electrically coupled with each other via the plurality of wires 4, respectively. Further, the sealing body 6 is formed over the front surface 51a of the wiring substrate 51 to seal the semiconductor chip 2 and the plurality of wires 4. As a result, the deformation of each wire 4 is prevented or inhibited.

Whereas, over the back surface 51b situated on the side of the wiring substrate 51 opposite to the front surface 51a, there are formed a plurality of solder balls 52. The plurality of solder balls 52 are electrically coupled with the bonding leads 53 formed on the front surface 51a side via a plurality of wires 55 formed over the wiring substrate 51, respectively. In other words, the plurality of pads 2c of the semiconductor chip 2 are electrically coupled with the plurality of solder balls 52, respectively. As a result, when the semiconductor device 50 is mounted on a mounting substrate not shown, the solder balls 52 are bonded and electrically coupled with the terminals (not shown) of the mounting substrate. In other words, the solder balls 52 serve as external electrodes (external coupling terminals) of the semiconductor device 50.

Whereas, as shown in FIG. 30, the plurality of solder balls 52 are arranged in a matrix on the back surface 51b side of the wiring substrate 51. The semiconductor device 50 is an area array type semiconductor device in which a plurality of external terminals are arranged in a matrix on the back surface (mounting surface) 51b side of the wiring substrate 51. The area array type semiconductor device can make the effective use of the back surface 51b side of the wiring substrate 51 as the space for disposing external electrodes. For this reason, the semiconductor device 50 is advantageous in that the number of external terminals can be increased as compared with semiconductor devices using a lead frame as the base material for mounting a semiconductor chip, such as QFP and QFN (Quad Flat Non-leaded Package).

Incidentally, the area array type semiconductor devices also include, other than a BGA (Ball Grid Array) type semiconductor device including the solder balls 52 mounted therein as external terminals as with the semiconductor device 50 shown in FIGS. 29 to 31, for example, a LGA (Land Grid Array) type semiconductor device from which the lands (external terminals) 54 for mounting bonding members such as solders are exposed. Alternatively, even in the case of a LGA type, a solder material may be coated thinly over the lands 54-exposed surface for easy mounting on a mounting substrate not shown.

<Manufacturing Steps of Area Array Semiconductor Device>

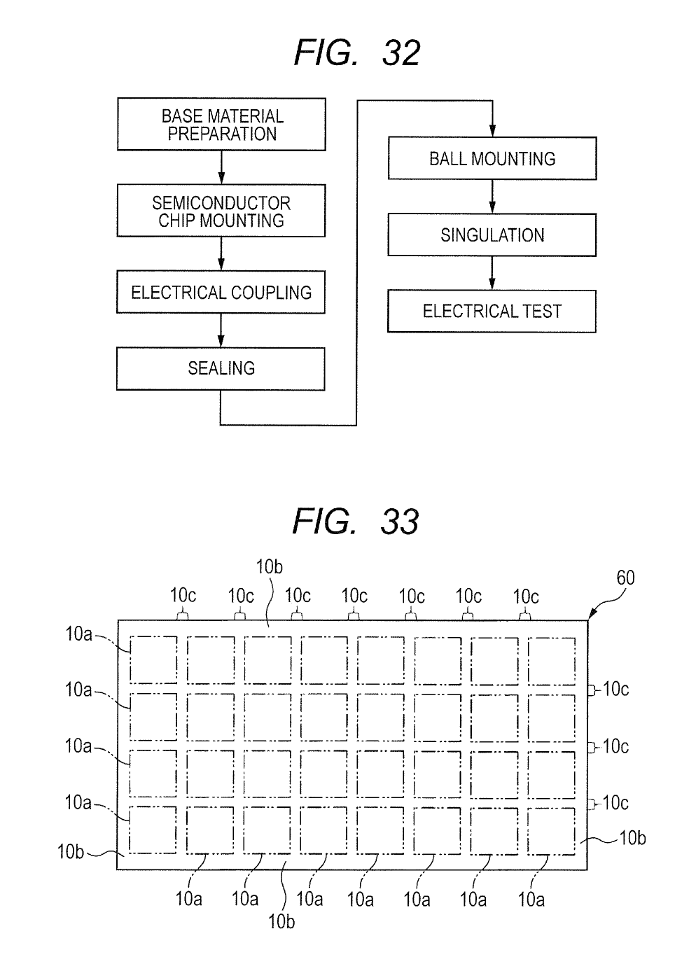

Then, the manufacturing steps of the semiconductor device 50 shown in FIGS. 29 to 31 will be described with an emphasis on the difference from the embodiments. FIG. 32 is an explanatory view showing the assembly flow of the semiconductor device shown in FIGS. 29 to 31.

1. Base Material Preparation Step

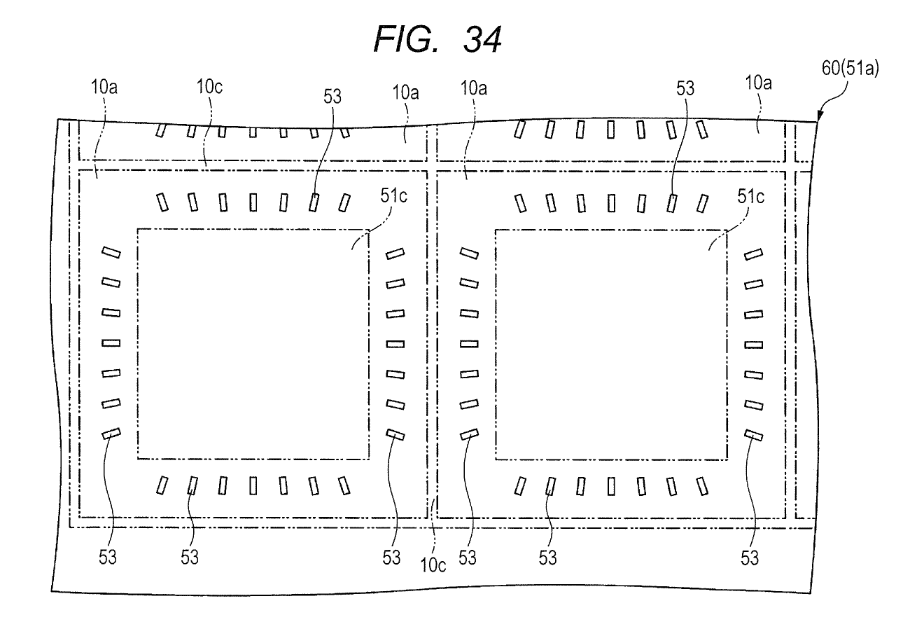

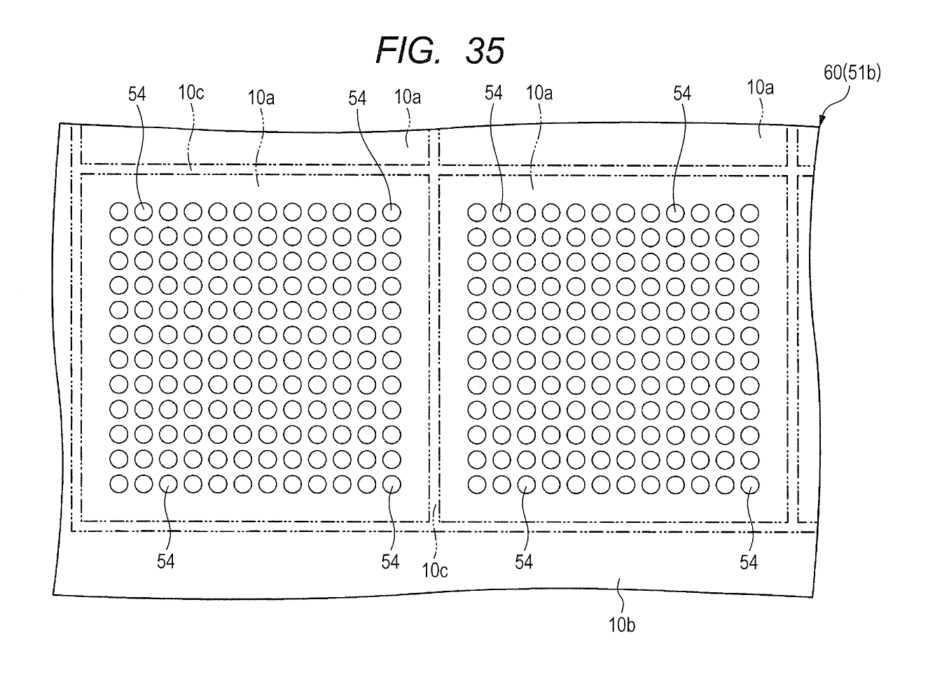

First, in the base material preparation step shown in FIG. 32, a wiring substrate (base material) 60 shown in FIGS. 33 to 35 is prepared. FIG. 33 is a plan view showing the overall structure of a lead frame prepared in the substrate preparation step shown in FIG. 32. FIG. 34 is an enlarged plan view of the product formation region of FIG. 33 on an enlarged scale. Whereas, FIG. 35 is an enlarged plan view showing the back surface side of the wiring substrate shown in FIG. 34. Incidentally, the preparation of the wiring substrate (base material) 60 includes, other than the embodiment in which the wiring substrate 60 shown in FIGS. 33 and 35 is previously manufactured to be used, embodiments in which the wiring substrates 60 manufactured in other places (other offices or other entrepreneurs) are purchased to be used.

As shown in FIG. 33, the wiring substrate 60 prepared in the present step includes a plurality of product formation regions 10a inside the frame part (frame body) 10b. Specifically, in the wiring substrate 60, a plurality of product formation regions 10a are arranged in a matrix. In other words, the wiring substrate 60 is a so-called multi-piece substrate. Thus, by using the wiring substrate 60 including a plurality of product formation regions 10a, it is possible to manufacture a plurality of semiconductor devices 50 (see FIG. 29) collectively. This can improve the manufacturing efficiency.

Each product formation region 10a corresponds to one wiring substrate 51 shown in FIGS. 29 to 30, and respective members of the wiring substrate 51 are formed therein. For example, as shown in FIG. 34, over the front surface 51a of each product formation region 10a, there are formed a chip mounting region (chip mounting part) 51c, and a plurality of bonding leads (terminals or bonding pads) 53 arranged in an array around the chip mounting region 51c, and exposed from the insulation film covering the front surface 51a. Whereas, as shown in FIG. 35, over the back surface 51b of the wiring substrate 60, in each product formation region 10a, a plurality of lands 54 exposed from the insulation film covering the back surface 51b are arranged in a matrix. Further, between respective product formation regions 10a, there is arranged a cutting region 10c which is a cutting allowance (to-be-cut region) to be cut in the singulation step shown in FIG. 32. Further, in each product formation region 10a of the wiring substrate 60, there are formed a plurality of wires 55 (see FIG. 31). The plurality of bonding leads 53 on the front surface 51a side and the plurality of lands 54 on the back surface 51b side are electrically coupled via the plurality of wires 55, respectively. The conductive patterns such as the plurality of bonding leads 53, the plurality of lands 54, and the plurality of wires 55 can be formed over the surface of the insulation layer serving as the core material by, for example, an electroplating method. Whereas, the plurality of wires 55 each includes an interlayer conductive path (via) for establishing a coupling between one surface and the other surface of the front surface 51a and the back surface 51b.

2. Semiconductor Chip Mounting Step

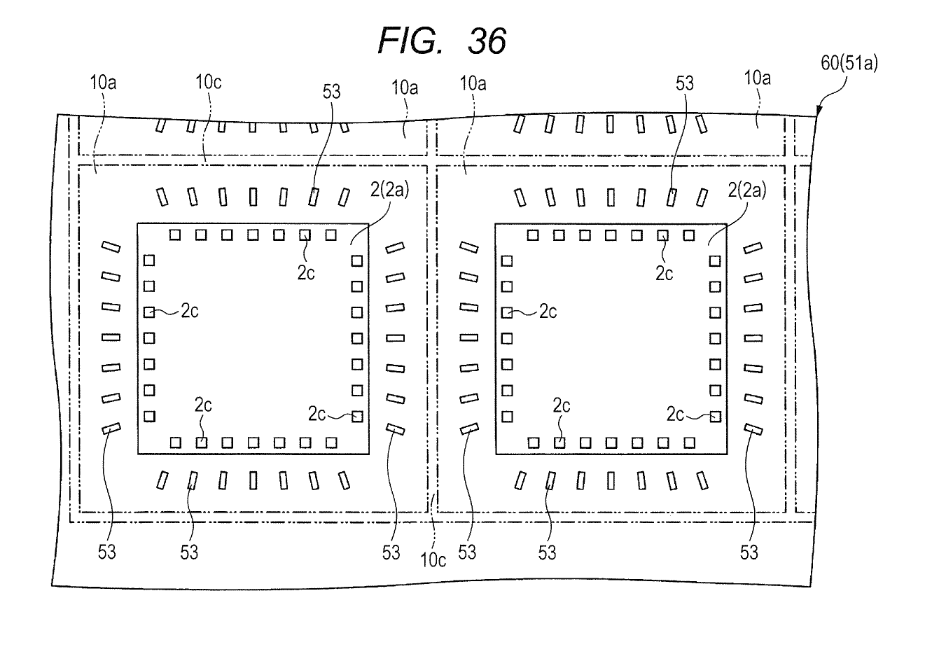

Then, in the semiconductor chip mounting step shown in FIG. 32, as shown in FIG. 36, over each product formation region 10a, the semiconductor chip 2 is mounted. FIG. 36 is an enlarged plan view showing the state in which a semiconductor chip is mounted over a chip mounting part shown in FIG. 35 via an adhesive material.

In the present embodiment, the semiconductor chip 2 is mounted (bonded and fixed) via, for example, a thermosetting resin, or the adhesive material 8 (see FIG. 31) obtained by mixing silver (Ag) particles in a thermosetting resin. The mounting system is assumed to be, for example, a so-called face-up mounting system in which mounting is performed with the back surface 2b of the semiconductor chip 2 (see FIG. 2) opposed to the top surface of the tab 3.

3. Electrical Coupling Step

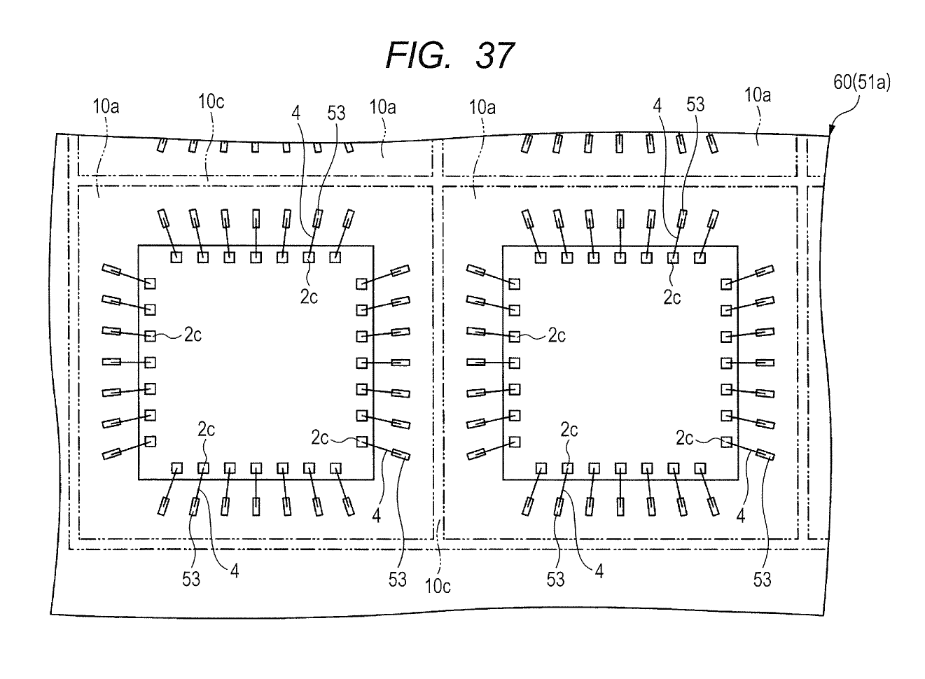

Then, in the electrical coupling step shown in FIG. 32, as shown in FIG. 37, the plurality of pads 2c of the semiconductor chip 2 and the plurality of leads 5 arranged around the semiconductor chip 2 are electrically coupled via the plurality of wires (conductive members) 4, respectively. FIG. 37 is an enlarged plan view showing the state in which a plurality of pads of the semiconductor chip and a plurality of bonding leads of the wiring substrate shown in FIG. 36 are electrically coupled via a plurality of wires, respectively.

4. Sealing Step

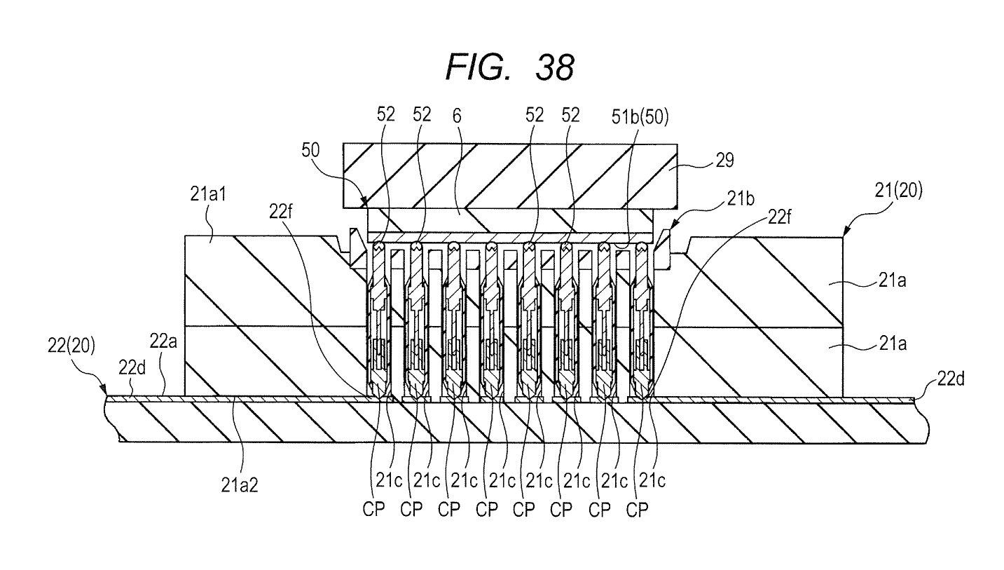

Then, in the sealing step shown in FIG. 32, as shown in FIG. 38, the sealing body 6 is formed, so that the semiconductor chip 2 (see FIG. 37) and the plurality of wires 4 (see FIG. 37) are sealed by the sealing body 6. FIG. 38 is a plan view showing the state in which the sealing body sealing the semiconductor chip and the plurality of wires shown in FIG. 37 is formed. Incidentally, FIG. 38 shows an example of a MAP (Matrix Array Package) system in which a plurality of product formation regions 10a are arranged in one cavity, and sealed collectively. In the present step, for example, by a so-called transfer mold system in which with the wiring substrate 60 shown in FIG. 37 interposed in a molding die not shown, a resin is pressed into the die, and then is cured, the sealing body 6 shown in FIG. 38 is formed.

5. Ball Mounting Step

Then, in the ball mounting step shown in FIG. 32, on the plurality of lands 54 formed on the back surface 51b side of the wiring substrate 60 shown in FIG. 35, the plurality of solder balls (solder materials) 52 are mounted, respectively. More particularly, first, as shown in FIG. 38, the wiring substrate 60 is vertically inverted. Thus, at the back surface 51b of the wiring substrate 60, on the plurality of lands 54 exposed from the insulation film, the plurality of solder balls 52 are arranged, respectively. Subsequently, the wiring substrate 60 including the solder balls 52 arranged thereon is subjected to a heat treatment (reflow). As a result, the plurality of solder balls 52 are respectively molten, and are bonded with the plurality of lands 54, respectively. In the reflow step, the wiring substrate 60 is arranged in a reflow furnace, and is heated to a higher temperature than the melting point of the solder balls 52, for example 260° C. or more. The insulation film covering the back surface 51b is a solder resist film, which can prevent bonding (bridging) between the adjacent solder balls 52.

Incidentally, in the present step, in order to bond the solder balls 52 and the lands 54, respectively, with reliability, bonding thereof is performed using, for example, an activator called flux. The flux can be removed by, for example, coming in contact with an oxide film formed on the surface of each solder ball 52. For this reason, it is possible to improve the wettability of the solder balls 52. When bonding is thus performed using a flux, washing for removing the residue of the flux component is performed after the heat treatment.

Whereas, in the case of the manufacturing step of LGA described above, the present step can be omitted. However, when a solder material is coated thinly over the lands 54-exposed surface, in the present step, a solder paste (a paste material of mixture of a solder component and a flux component) is coated.

6. Singulation Step

Then, in the singulation step shown in FIG. 32, the wiring substrate 60 (and the sealing body 6) is (are) cut along the cutting region (dicing line) 10c shown in FIG. 34, thereby to singulate respective product formation regions 10a. As a result, it is possible to obtain the semiconductor devices 50 (FIG. 29 to see FIG. 31). The singulation method has no particular restriction. There is applicable a cutting method in which a dicing blade (cutting blade) is caused to run along the cutting region 10c to perform cutting. Incidentally, the plurality of semiconductor devices 50 obtainable in the present step are each in a pretest semifinished product (assembly) form. Therefore, after the present step, the visual inspection step and the electrical test step shown in FIG. 32 are performed. Then, the successful ones become finished semiconductor devices 1.

7. Electrical Test Step

Then, in the electrical test step shown in FIG. 3, a current is passed through the semiconductor device, thereby to conduct a test for checking that there is no disconnection in the circuit, and that the device has prescribed (allowable or higher) electrical characteristics. Further, in the present step, based on the results of the electrical test, whether the device is a good product or a defective product is determined. Then, the defective products are removed. Below, the electrical test step on the area array type semiconductor device will be described with an emphasis on the difference from the foregoing embodiments.

When the electrical test is performed on the area array type semiconductor device 50, first, as shown in FIG. 38, the disposition of the terminals CP is different. FIG. 38 is an enlarged cross-sectional view showing the periphery of the socket of the inspection device which is a modified example with respect to FIG. 11. In the semiconductor device 50, the solder balls 52 which are external terminals are arranged in a matrix on the back surface 51b of the wiring substrate 51 as shown in FIG. 30. Accordingly, the terminals CP are arranged in rows and columns (in a matrix) between the back surface 51b of the wiring substrate 51 and the front surface 22a of the test substrate 22 as shown in FIG. 38, corresponding to the array of the solder balls 52. Whereas, it is difficult to press the tip ends of the external terminals (leads 5) with the pressing jigs 28 as shown in FIG. 11. Therefore, for example, a pressing jig (pressing member) 29 as shown in FIG. 38 is arranged over the top surface of the sealing body 6, and presses the whole semiconductor device 50 toward the terminals CP. As a result, from the relationship between the pressing force from the pressing jig 29 and the elastic force of the spring part SP (see FIG. 12) of each terminal CP, the plurality of terminals CP and the plurality of solder balls 52 can be brought into contact with each other, respectively, within the range of a prescribed contact pressure (contact load).

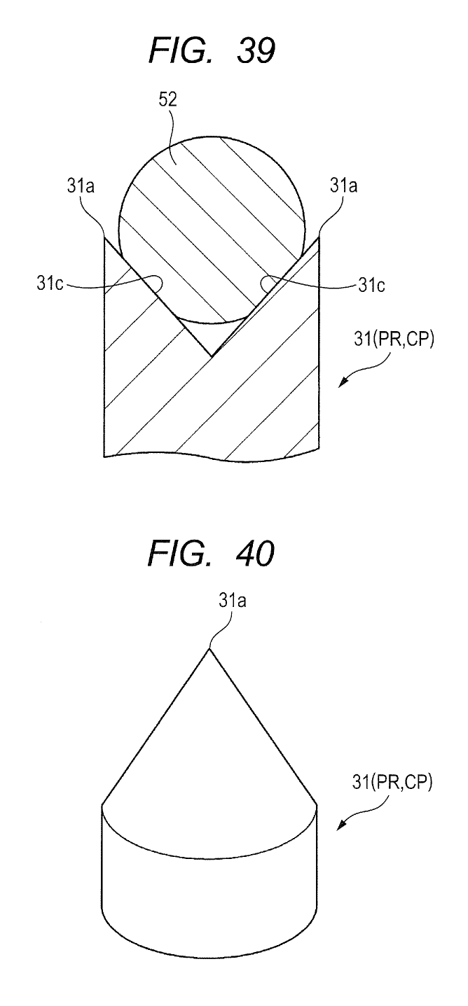

Incidentally, when the solder material is formed in a ball shape as with the solder ball 52, the thickness of the solder material tends to be larger than in the case described in the foregoing embodiments. For example, in the foregoing embodiments, the thickness of the metal film 9 which is a solder plating film shown in FIG. 2 is smaller than that of the underlying base material part (underlayer part), and is, for example, about 10 μm to 20 μm. On the other hand, the thickness of the solder ball 52 is equal to the diameter of the ball, and hence tends to be larger than this. For this reason, when the electrical test is performed with the terminal CP biting into the solder ball 52, the end of the contact region 31 of the terminal CP tends to be collapsed (to be less likely to be flattened).

Whereas, when the terminal CP is caused to bite into a ball-like external terminal such as the solder ball 52, it is possible to cause apart of the solder ball 52 to bite not into the cusp part (apex part) 31a of the contact region of the terminal CP but into the ridgeline part (ridge part or inclined part) 31c between the cusp parts 31a as shown in FIG. 39. FIG. 39 is an enlarged cross-sectional view showing one example when the solder ball and the contact terminal are brought into contact with each other. In the case where the solder ball 52 is caused to bite into the cusp part 31a, each time when the electrical test is performed, the cusp part 31a is first brought into contact therewith. The contact area at the time of first contact is small, so that wear and collapse tend to proceed from the cusp part 31a. On the other hand, as shown in FIG. 39, when the solder ball 52 is caused to bite into the ridgeline part 31c, the contact area at the time of first contact between the solder ball 52 and the terminal CP becomes larger. Accordingly, the pressure can be dispersed. For this reason, proceeding of wear or collapse can be retarded to elongate the life.

Whereas, in the foregoing embodiments, a description was given to the embodiments in which the plurality of cusp parts 31a were formed in the contact region 31. However, the number of the cusp parts 31a is not limited to a plural number. For example, as shown in FIG. 40, a shape having one cusp part 31a is acceptable. FIG. 40 is a perspective view showing the contact region periphery of a test terminal which is a modified example with respect to FIGS. 13 and 14 on an enlarged scale. As shown in FIG. 40, the terminal CP having one cusp part 31a is effectively applicable to, for example, the electrical test step of the LGA type semiconductor device. In the case of the LGA type semiconductor device, an insulation film such as a solder resist film is arranged around each land 54 (see FIG. 31) to be contact with the terminal CP. Thus, when misalignment occurs upon causing the terminal CP to bite into the land 54, the cusp parts 31a may damage the insulation film. Under such circumstances, when the number of the cusp parts 31a is one as shown in FIG. 40, it is possible to reduce the risk for the cusp part 31a to damage the insulation film.

The present invention is widely usable for semiconductor devices to be subjected to an electrical test.

What is claimed is:

1. A method for manufacturing a semiconductor device, comprising the steps of:
(a) preparing a base material including a chip mounting part and a plurality of external terminals;
(b) mounting a semiconductor chip including a plurality of electrode pads over the chip mounting part of the base material;
(c) electrically coupling the electrode pads of the semiconductor chip and the external terminals of the base material via a plurality of conductive members, respectively; and
(d) bringing the external terminals of the base material into contact with contact regions of a plurality of test terminals, thereby electrically coupling the semiconductor chip and a test circuit, and performing an electrical test,
each of the contact regions of the test terminals including a core material formed of a first alloy, and a metal film covering the core material, and
the metal film being formed of a second alloy higher in hardness than the first alloy.

2. The method for manufacturing a semiconductor device according to claim 1,
wherein each end of the contact regions of the test terminals is in a pointed shape, and
wherein in the step (d), the electrical test is performed with a part of the contact region of each of the test terminals biting into each of the external terminals.

3. The method for manufacturing a semiconductor device according to claim 2,
wherein the test terminals are repeatedly used for the electrical test of a plurality of semiconductor devices.

4. The method for manufacturing a semiconductor device according to claim 3,
wherein in the step (d), (d1) until the core material of the metal film is exposed, the metal film and each of the external terminals are brought into contact with each other, thereby to perform the electrical test, and (d2) after the core material is exposed, the core material and the external terminals are brought into contact with each other, thereby to perform the electrical test.

5. The method for manufacturing a semiconductor device according to claim 4,
wherein the first alloy forming the core material and the second alloy forming the metal film have a constituent element included in the largest content therein in common.

6. The method for manufacturing a semiconductor device according to claim 5,
wherein each surface of the external terminals is formed of a solder, and
wherein each of the first and second alloys is a palladium alloy including a palladium (Pd) element in the largest content among constituent elements.

7. The method for manufacturing a semiconductor device according to claim 6,
wherein each of the first and second alloys includes an element lower in electrical resistivity than the palladium (Pd) element.

8. The method for manufacturing a semiconductor device according to claim 5,
wherein the second alloy includes a cobalt (Co) element other than the palladium (Pd) element.

9. The method for manufacturing a semiconductor device according to claim 4,
wherein in the step (d), (d3) after repeated uses, the contact region of the core material is polished and sharpened, and then, the core material and each of the external terminals are brought into contact with each other, thereby to perform the electrical test.

10. The method for manufacturing a semiconductor device according to claim 9,
wherein when the contact region of the core material is polished, with a polishing jig pressed against a flat surface which is the to-be-polished surface of the core material, the polishing jig is vibrated along the flat surface.

11. The method for manufacturing a semiconductor device according to claim 10,
wherein when the contact region of the core material is polished, the polishing jig is vibrated in a plurality of directions crossing each other along the flat surface.

12. The method for manufacturing a semiconductor device according to claim 10,
wherein when the contact region of the core material is polished, the polishing jig is rotationally moved along the flat surface.

13. The method for manufacturing a semiconductor device according to claim 10,
wherein over the polishing surface of the polishing jig, an elastic body layer, and a polishing abrasive grain layer including a plurality of abrasive grains bonded thereover via a resin are successively stacked.

14. A method for manufacturing a semiconductor device, comprising the steps of:
(a) preparing a base material including a chip mounting part and a plurality of external terminals;
(b) mounting a semiconductor chip including a plurality of electrode pads over the chip mounting part of the base material;
(c) electrically coupling the electrode pads of the semiconductor chip and the external terminals of the base material via a plurality of conductive members, respectively; and
(d) bringing the external terminals of the base material into contact with contact regions of a plurality of test terminals, thereby electrically coupling the semiconductor chip and a test circuit, and performing an electrical test,
each surface of the external terminals being formed of a solder, and
the contact regions of the test terminals being formed of a palladium alloy including a palladium (Pd) element in the largest content among constituent elements.

15. The method for manufacturing a semiconductor device according to claim 14,
wherein each end of the contact regions of the test terminals is in a pointed shape, and
wherein in the step (d), the electrical test is performed with apart of the contact region of each of the test terminals biting into each of the external terminals.

16. The method for manufacturing a semiconductor device according to claim 15,
wherein the palladium alloy includes an element lower in electrical resistivity than the palladium (Pd) element.

17. The method for manufacturing a semiconductor device according to claim 16,
wherein the test terminals are repeatedly used for the electrical test of a plurality of semiconductor devices.

18. The method for manufacturing a semiconductor device according to claim 17,
wherein in the step (d), (d1) after repeated uses, the contact region of the core material is polished and sharpened, and then, the core material and each of the external terminals are brought into contact with each other, thereby to perform the electrical test.

19. The method for manufacturing a semiconductor device according to claim 18,
wherein when the contact region of the core material is polished, with a polishing jig pressed against a flat surface which is the to-be-polished surface of the core material, the polishing jig is vibrated along the flat surface.

20. The method for manufacturing a semiconductor device according to claim 19,
wherein when the contact region of the core material is polished, the polishing jig is vibrated in a plurality of directions crossing each other along the flat surface.

21. The method for manufacturing a semiconductor device according to claim 19,
wherein when the contact region of the core material is polished, the polishing jig is rotationally moved along the flat surface.

22. The method for manufacturing a semiconductor device according to claim 19,
wherein over the polishing surface of the polishing jig, an elastic body layer, and a polishing abrasive grain layer including a plurality of abrasive grains bonded thereover via a resin are successively stacked.
